(19) United States
(12) Patent Application Publication
(10) Pub. No.: US 2024/0224652 A1
(43) Pub. Date: Jul. 4, 2024

(54) DISPLAY DEVICE

(71) Applicant: LG Display Co., Ltd., Seoul (KR)

(72) Inventors: Taehee KO, Seoul (KR); Sunghee PARK, Goyang-si, Gyeonggi-do (KR)

(73) Assignee: LG Display Co., Ltd., Seoul (KR)

(21) Appl. No.: 18/397,137

(22) Filed: Dec. 27, 2023

(30) Foreign Application Priority Data
Dec. 29, 2022 (KR) 10-2022-0189585
Dec. 19, 2023 (KR) 10-2023-0185448

(51) Int. Cl. H10K 59/131; H10K 59/88

(52) U.S. Cl. CPC H10K 59/131; H10K 59/88

(57) ABSTRACT

A display device may include a display panel having a display area and a non-pad area; a plurality of transmissive areas disposed in the non-pad area and spaced apart from each other in a first direction and a second direction different from the first direction; a circuit area disposed between adjacent ones of the plurality of transmissive areas; a plurality of connection lines, each connection line being disposed between adjacent ones of the plurality of transmissive areas; and a plurality of wiring lines disposed in the circuit area. Each of the plurality of wiring lines may extend so as to intersect a corresponding one of the plurality of connection lines. The plurality of wiring lines may be disposed in different layers. A first undercut structure may be formed under each of the plurality of wiring lines. Each connection line may be disposed at a corresponding one of blocking channels.

### CROSS-REFERENCE TO RELATED APPLICATION

This application claims the benefit of and priority to Korean Patent Application No. 10-2022-0189585 filed on Dec. 29, 2022 and Korean Patent Application No. 10-2023-0185448 filed on Dec. 19, 2023, the entirety of each of which is incorporated herein by reference for all purposes.

### BACKGROUND

### Field

The present disclosure relates to a display device, and particularly to, for example, without limitation, a display device capable of blocking a moisture penetrating path to an organic light-emitting element to improve reliability of the organic light-emitting element.

### Discussion of the Related Art

A display device may be used in various electronic devices, such as TVs, mobile phones, laptops and tablets. Thus, research to develop thinner, lighter, and lower power consuming display devices is continuing.

Examples of display devices may include a liquid crystal display device (LCD), a plasma display device (PDP), a field emission display device (FED), an electro-wetting display device (EWD), and an organic light-emitting display device (OLED).

An organic light-emitting display device (OLED) may include a plurality of pixel areas disposed in a display area where an image is displayed, and a plurality of organic light-emitting elements corresponding to the plurality of pixel areas. Since an organic light-emitting element is a self-light-emitting element that emits light by itself, the organic light-emitting display device provides the advantages of faster response speed, greater luminous efficiency, higher luminance, larger viewing angle, and excellent contrast ratio and color reproduction compared to the liquid crystal display device.

The organic light-emitting element may include an organic material that may be easily deteriorated by moisture. Accordingly, research is being conducted to block a moisture penetrating path in order to prevent the organic material from deteriorating.

Moreover, demand for a display apparatus capable of realizing a large-area screen in which a plurality of display devices are arranged, and a display apparatus having various sizes in which a plurality of display devices are arranged is increasing. Accordingly, it has become a major challenge to be able to implement a display apparatus of various sizes while blocking moisture and oxygen from penetrating the organic light-emitting elements to improve the quality of the display apparatus.

The description provided in the discussion of the related art section should not be assumed to be prior art merely because it is mentioned in or associated with that section. The discussion of the related art section may include information that describes one or more aspects of the subject technology, and the description in this section does not limit the invention.

### SUMMARY

The inventors of the present disclosure have recognized the problems and disadvantages of the related art, have performed extensive research and experiments, and have developed a new invention as described herein.

One or more aspects of the present disclosure are directed to providing a display device which can be cut into a display device of various sizes and in which a moisture penetrating path (which is one of the causes of deteriorating an organic light-emitting element) can be blocked, or prevented from being formed, to maintain performance of the organic light-emitting element.

One or more aspects of the present disclosure are directed to providing a display device capable of preventing an organic material layer, disposed in an area other than a display area, from acting as a moisture penetrating path.

Other aspects, features and advantages of the present disclosure are set forth in the present disclosure and will also be apparent from the present disclosure or may be learned by practice of the inventive concepts provided herein. Other aspects, features and advantages of the present disclosure may be realized and attained by the descriptions provided in the present disclosure, including the claims and the drawings.

A display device according to one or more example embodiments of the present disclosure may include a display panel including a display area and a non-pad area located outside the display area; a plurality of transmissive areas disposed in the non-pad area and spaced apart from each other in a first direction and a second direction different from the first direction; a circuit area disposed between adjacent ones of the plurality of transmissive areas; a plurality of connection lines, wherein each connection line is disposed between adjacent ones of the plurality of transmissive areas; and a plurality of wiring lines disposed in the circuit area, wherein each of the plurality of wiring lines extends so as to intersect a corresponding one of the plurality of connection lines, and wherein the plurality of wiring lines are disposed in different layers, wherein a first undercut structure is formed under each of the plurality of wiring lines.

A display device according to one or more example embodiments of the present disclosure may include a display panel including a display area and a non-pad area located outside the display area; a plurality of transmissive areas disposed in the non-pad area and spaced apart from each other in a first direction and a second direction different from the first direction; a circuit area disposed between adjacent ones of the plurality of transmissive areas; a plurality of blocking channels, wherein each blocking channel is disposed between adjacent ones of the plurality of transmissive areas; and a plurality of wiring lines disposed in the circuit area, wherein each of the plurality of wiring lines extends so as to intersect a corresponding one of the plurality of blocking channels, wherein the plurality of wiring lines are disposed in different layers, and wherein a first undercut structure is formed under each of the plurality of wiring lines.

According to one or more example embodiments of the present disclosure, breaking (or splitting or dividing) the organic material layer which may act as a moisture penetrating path in a display device that can be cut to implement a display device of various sizes may allow the performance and lifespan of the organic light-emitting element to be maintained for a long period.

According to one or more example embodiments of the present disclosure, maintaining the performance and lifespan of the organic light-emitting element for a long period may secure the quality of an image in the display device at a low power level, thereby reducing power consumption.

Moreover, according to one or more example embodiments of the present disclosure, introducing the same array structure, as that of the display area, into an area other than the display area in a display device that can be cut may improve the manufacturing process.

Moreover, according to one or more example embodiments of the present disclosure, inserting a dummy pattern into a corner of the non-pad area of the display device that can be cut may further delay (or reduce) the penetration of moisture and oxygen, thereby increasing the lifespan of the display device and further improving reliability.

Moreover, according to one or more example embodiments of the present disclosure, breaking (or splitting) the organic material layer with a multilayer structure in a direction overlapping the direction of the moisture penetrating path in the non-pad area may prevent (or significantly reduce) the penetration of moisture and oxygen into the display area. Accordingly, the lifespan of the organic light-emitting element disposed in the display area may be lengthened, and the display device may operate using low power.

Features, aspects and advantages of the present disclosure are not limited to those described above, and other features, aspects and advantages not described will be clearly understood by those skilled in the art from the present disclosure.

It is to be understood that both the foregoing description and the following description of the present disclosure are exemplary and explanatory, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles of the disclosure.

FIG. 1 is a schematic plan view of a display device according to an embodiment of the present disclosure.

FIG. 2A to FIG. 2C are diagrams showing a portion of a non-pad area of a display device according to an embodiment of the present disclosure.

FIG. 3 is an enlarged plan view showing a portion of a non-pad area of a display device according to another embodiment of the present disclosure.

FIG. 4A and FIG. 4B are diagrams respectively showing portions of FIG. 3.

FIG. 5 is a schematic perspective view according to another embodiment of FIG. 3.

FIG. 6A is an enlarged plan view showing a portion of a non-pad area according to still another embodiment of the present disclosure.

FIG. 6B is an enlarged plan view showing a portion of a display area according to another embodiment of the present disclosure.

FIGS. 7 to 14 are cross-sectional views respectively showing portions of FIG. 6.

FIG. 15 is an enlarged plan view of an area 15 depicted in FIG. 1.

FIG. 16 is an enlarged plan view of an area 16 depicted in FIG. 15.

FIG. 17 is a cross-sectional view showing a configuration in which a moisture invasion path is blocked by a multi-layer structure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and convenience.

### DETAILED DESCRIPTIONS

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order depending on a function or operation involved.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

The shapes, sizes, areas, ratios, angles, numbers, and the like disclosed in the drawings for describing embodiments of the present disclosure are merely examples, and thus, the present disclosure is not limited to the illustrated details.

When the term “comprise,” “have,” “include,” “contain,” “constitute,” “make up of,” “formed of,” or the like is used, one or more other elements may be added unless a term such as “only” or the like is used. The terms used in the present disclosure are merely used in order to describe particular embodiments, and are not intended to limit the scope of the present disclosure. The terms used herein are merely used in order to describe example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. “Embodiments,” “examples,” “aspects” and the like should not be construed to be preferred or advantageous over other implementations. Further, the term “may” encompasses all the meanings of the term “can.”

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

In describing a positional relationship, where the positional relationship between two parts (e.g., layers, films, regions, components, sections, or the like) is described, for example, using “on,” “on top of,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” “adjacent to,” “beside,” or “next to” another structure, this description should be construed as including a case in which the structures contact each other directly as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It is understood that, although the terms “first,” “second,” and the like may be used herein to describe various elements (e.g., layers, films, regions, components, sections, or the like), these elements should not be limited by these terms. These terms are used only to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element or layer is “connected,” “coupled,” “attached,” or “adhered” to another element or layer, the element or layer can not only be directly connected, coupled, attached, or adhered to another element or layer, but also be indirectly connected, coupled, attached, or adhered to another element or layer with one or more intervening elements or layers disposed or interposed between the elements or layers, unless otherwise specified.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

The terms such as a “line” or “direction” should not be interpreted only based on a geometrical relationship in which the respective lines or directions are parallel or perpendicular to each other, and may be meant as lines or directions having wider directivities within the range within which the components of the present disclosure can operate functionally.

The term “at least one” should be understood as including any and all combinations of one or more of the associated listed items. For example, the meaning of “at least one of a first item, a second item, and a third item” denotes the combination of items proposed from two or more of the first item, the second item, and the third item as well as only one of the first item, the second item, or the third item.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or”. That is, unless otherwise stated or clear from the context, the expression that “x uses a or b” means any one of natural inclusive permutations. For example, “a or b” may mean “a,” “b,” or “a and b.”

Features of various embodiments of the present disclosure may be partially or entirely coupled to or combined with each other, may be technically associated with each other, and may be operated, linked or driven together. The embodiments of the present disclosure may be implemented or carried out independently of each other or may be implemented or carried out together in a co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

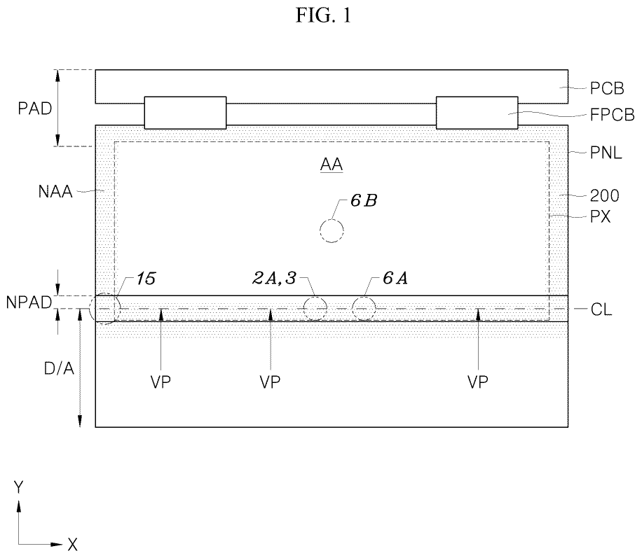

FIG. 1 is a schematic plan view of a display device according to an example embodiment of the present disclosure. FIG. 1 shows a display panel PNL, a dam pattern 200, a printed circuit board PCB, and a flexible circuit board FPCB of the display device, without showing various other components of the display device, for convenience of illustration.

Referring to FIG. 1, the display panel PNL of the display device according to an example embodiment of the present disclosure may include a display area AA, a pad area PAD, and a non-pad area NPAD.

The display area AA may be an area where an image is displayed and may include a plurality of sub-pixels. The display device according to an example embodiment of the present disclosure may be embodied as a transparent display device that displays an image and transmits light therethrough so that an object disposed in rear of the display panel PNL can be recognized by a user. In one of techniques for implementing a transparent display panel PNL, a sub-pixel area may be divided into a transmissive area and a circuit area, and the transmissive area may transmit light therethrough so that a rear surface of the display panel may be recognized by the user. To this end, the transmissive area may be an area in which an opaque material or a reflective material is not disposed. Moreover, an organic material layer as a light-emitting layer may be disposed in each of the transmissive area and the circuit area. An organic light-emitting element may include the organic material layer, an anode, and a cathode, where the organic material layer may be disposed between the anode and the cathode. In one example, the transmissive area may include the organic material layer and the cathode excluding the anode.

Each of the sub-pixels disposed in the display area may emit light of one color. Three or four or more sub-pixels adjacent to each other and emitting light of different colors among the plurality of sub-pixels may constitute one pixel area emitting light of various colors. That is, the pixel area may display various colors and emit an image to the display area AA via a combination of light beams respectively emitted from two or more sub-pixels which are adjacent to each other and constitute one pixel area. For example, the sub-pixels constituting one pixel area may emit light beams corresponding to the colors of green (G), blue (B), and red (R), or emit light beams corresponding to the colors of green (G), blue (B), red (R), and white (W).

The pad area PAD may be an area which may be disposed in a non-display area NAA other than the display area AA, and in which the flexible circuit board FPCB and the printed circuit board PCB are disposed. The flexible circuit board FPCB and the printed circuit board PCB may be disposed at or on at least one side edge of the display panel PNL. An integrated circuit chip may be disposed on the flexible circuit board FPCB. The flexible circuit board FPCB may be combined with the printed circuit board PCB so as to supply power and various signals for driving organic light-emitting elements received from the printed circuit board PCB to the display area AA. For example, the various signals may include a high potential voltage, a low potential voltage, a scan signal, or a data signal.

The printed circuit board PCB may supply the signals to the integrated circuit chip disposed on the flexible circuit board FPCB. Various components for supplying the various signals to the integrated circuit chip may be disposed on the printed circuit board PCB. In FIG. 1, the printed circuit board PCB is shown as a single PCB. However, the present disclosure is not limited thereto. For example, a plurality of printed circuit boards PCB may be disposed at or on one side edge of the display panel PNL.

The non-pad area NPAD may be disposed in the non-display area NAA other than the display area AA, and may be located at or on the other side edge opposite to the one side edge of the display panel PNL on which the pad area PAD is disposed. The non-pad area NPAD may be defined by a cutting line CL.

As the demand for display devices of various sizes increases, research on techniques of implementing the display devices of various sizes is being conducted. One of the techniques is to introduce the display panel PNL which can be cut. The display panel PNL which can be cut has the cutting line CL disposed on the other side edge opposite to the pad area PAD. A to-be-removed area D/A is an area to be isolated and removed from the display panel PNL when the display panel PNL is cut along the cutting line CL. The to-be-removed area D/A is removed from the display panel PNL via cutting along the cutting line CL such that a size of the display device can be adjusted. In addition, the other side edge portion opposite to the pad area PAD, excluding the to-be-removed area D/A removed via the cutting along the cutting line CL, may be the non-pad area NPAD.

In the display panel in which a size of a display device is fixed, the sub-pixel having the transmissive area and the circuit area is disposed only in the display area AA. However, in the display panel PNL which can be cut, an area PX in which a plurality of sub-pixels are disposed may extend into the non-pad area NPAD. In other words, a plurality of transmissive areas including an organic material layer and a plurality of circuit areas may be disposed in the non-pad area NPAD. The organic material layer may be easily deteriorated by moisture or oxygen.

Accordingly, an area where the organic material layer is disposed in the other side edge of the display panel PNL where the non-pad area NPAD is located may become a moisture invasion path. A moisture invasion path direction VP in which moisture invasion proceeds may be a direction from the other side edge of the display panel PNL toward the display area AA, as indicated by the arrow in FIG. 1. In addition, the organic material layer extending along the moisture invasion path direction VP acts as the moisture invasion path along which the moisture may invade into the display area AA.

Therefore, in one or more aspects, it is important to prevent the moisture or oxygen from penetrating or flowing into the display area through the organic material layer disposed in the non-pad area NPAD toward which the moisture penetrating path direction VP faces.

A dam pattern 200 may be disposed to prevent penetration of moisture and oxygen into an organic light-emitting element of the display panel PNL. The dam pattern 200 may have a shape surrounding fours side edges of the display panel PNL. The dam pattern 200 may serve to prevent the oxygen and moisture from penetrating into the display area AA.

In an example embodiment of the present disclosure, not only placing the dam pattern 200 but also breaking the organic material layer, which is disposed in the non-pad area NPAD and serves as the moisture or oxygen penetrating path, may prevent the moisture or oxygen from penetrating the display area AA. Further details are described below with reference to other drawings in this disclosure.

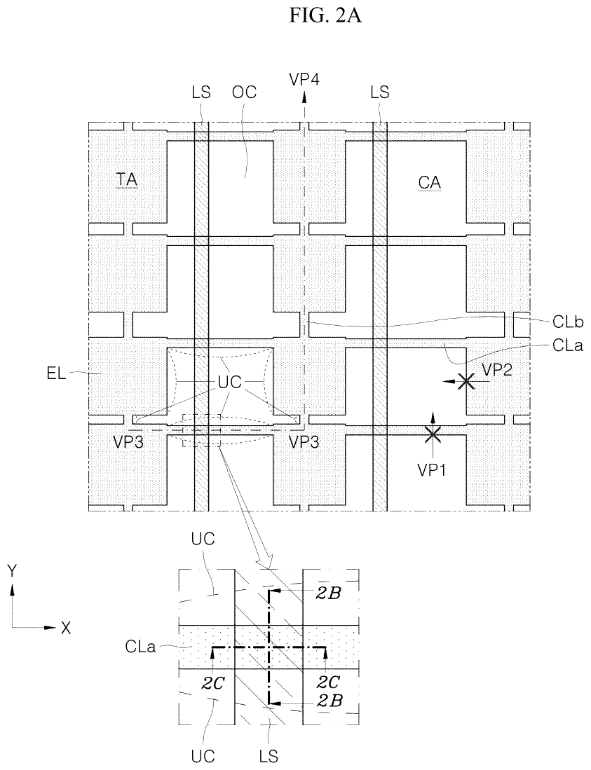

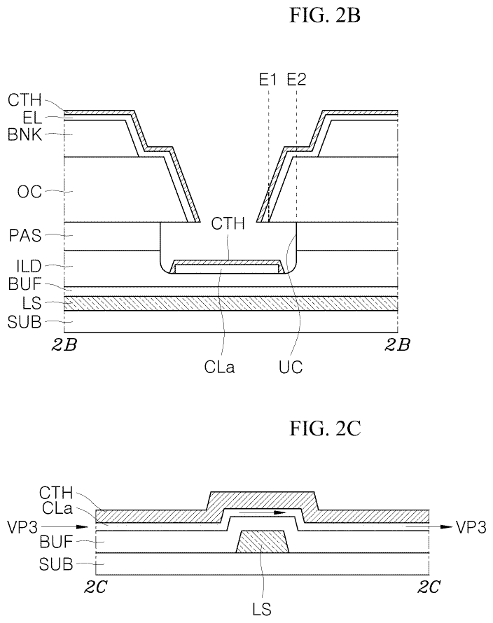

FIG. 2A to FIG. 2C are plan views showing an enlarged portion of the non-pad area of the display device according to an example embodiment of the present disclosure. FIG. 2B is a cross-sectional view cut along a 2B-2B line in an area of FIG. 2A. FIG. 2C is a cross-sectional view cut along a 2C-2C line in the area of FIG. 2A.

Referring to FIG. 2A to FIG. 2C, the non-pad area NPAD may include a plurality of transmissive areas TA and a plurality of circuit areas CA. The transmissive area TA may be an area where an opaque or reflective material is not disposed.

The plurality of transmissive areas TA may be arranged to be spaced apart from each other while each of the circuit areas CA is disposed between adjacent ones of the plurality of transmissive areas TA. The transmissive areas TA may be arranged to be spaced apart from each other in a first direction and a second direction different from the first direction. In this regard, the first direction may be an X-axis direction and the second direction may be a Y-axis direction. Additionally, the first direction may be a row direction, and the second direction may be a column direction.

A light blocking layer wiring LS may be included in a substrate SUB of the circuit area CA of the non-pad area NPAD. The light blocking layer wiring LS may extend along the second direction in which the transmissive areas are arranged. On the light blocking layer wiring LS, a buffer insulation layer BUF, an interlayer insulation layer ILD, a passivation layer PAS, an overcoat layer OC, a bank BNK, an organic material layer EL, and a cathode layer CTH may be disposed. In addition, although not shown in the drawings for convenience of illustration, an encapsulation layer that seals the underlying structures may be disposed on top of the cathode layer CTH.

In FIG. 2A, for convenience of illustration, the organic material layer EL is shown to be disposed only in the transmissive area TA. However, the organic material layer EL may be disposed across an entire surface of the display device. Accordingly, the organic material layer EL may be disposed on top of the overcoat layer OC of the circuit area CA.

As the organic material layer EL is disposed on top of the overcoat layer OC of the circuit area CA, a first connection line CLa and a second connection line CLb may be formed between adjacent transmissive areas TA to ensure the reliability of the display device. For example, when the transmissive area TA is surrounded only with the overcoat layer OC, a problem may arise where moisture invades into the display area AA through the organic material layer EL disposed on top of the overcoat layer OC.

To prevent the moisture from penetrating into the display area AA, an undercut structure UC may be disposed under the overcoat layer OC in the circuit area CA. Specifically, the undercut structure UC may be located along a border of the transmissive area TA. When the undercut structure UC is formed under the overcoat layer OC, and then the organic material layer EL is stacked thereon, the organic material layer EL may be discontinuous, and thus portions of the organic material layer El in adjacent transmissive areas TA may be divided from each other. Thus, the first connection line CLa and the second connection line CLb may be formed. For example, the first connection line CLa may be disposed between transmissive areas TA adjacent to each other in the first direction (e.g., the X-axis direction), and the second connection line CLb may be disposed between transmissive areas TA adjacent to each other in the second direction (e.g., the Y-axis direction).

In addition, the undercut structure UC is disposed under the overcoat layer OC on both opposing sides of each of the first connection line CLa and the second connection line CLa to break the organic material layer EL on top of the overcoat layer OC, thereby ensuring reliability of the display device. The undercut structure UC may be formed by removing the interlayer insulation layer ILD and the passivation layer PAS inwardly so that a side end E1 of the overcoat layer OC protrudes beyond aa side end E2 of the interlayer insulation layer ILD or the passivation layer PAS.

Referring again to FIG. 2A, the first connection line CLa may be disposed between the transmissive areas TA arranged in the first direction (e.g., the X-axis direction), and the second connection line CLb may be disposed between the transmissive areas TA arranged in the second direction (e.g., the first connection line CLa and the second connection line CLb may include the same material as that of the organic material layer EL).

The undercut structure UC may be disposed under a portion of the overcoat layer OC on each of both opposing sides in the second direction of the first connection line CLa extending in the first direction. Alternatively, the undercut structure UC may be disposed under a portion of the overcoat layer OC on each of both opposing sides in the first direction of the second connection line CLa extending in the second direction.

Referring to FIG. 2A and FIG. 2B, the undercut structure UC may be disposed under a portion of the overcoat layer OC on each of both opposing sides in the second direction (Y-axis direction) of the first connection line CLa extending in the first (X-axis) direction. The undercut structure UC may disconnect the first connection line CLa from the organic material layer EL on the overcoat layer OC on each of both opposing sides in the second direction (Y-axis direction) of the first connection line CLa extending in the first (X-axis) direction, thereby preventing a moisture invasion path VP1 extending in the second direction (Y-axis) direction from being formed. Further, the undercut structure UC may be disposed under a portion of the overcoat layer OC on each of both opposing sides in the first direction of the second connection line CLa extending in the second direction. In this case, the undercut structure UC may disconnect the second connection line CLb from the organic material layer EL on the overcoat layer OC on each of both opposing sides in the first direction (X-axis direction) of the second connection line CLb extending in the second (Y-axis) direction, thereby preventing another moisture invasion path VP2 extending in the first direction (X-axis) direction from being formed.

However, referring to FIG. 2A and FIG. 2C, in the transmissive areas TA arranged to be spaced apart from each other in the first direction (X-axis direction), another moisture invasion path VP3 extending in the first direction (X-axis direction) through the first connection line CLa may be formed. In addition, in the transmissive areas TA arranged to be spaced apart from each other in the second direction (Y-axis direction), still another moisture invasion path VP4 extending to the display area AA through the second connection line CLb along the second direction (Y-axis direction) may be formed. Thus, the moisture or oxygen may invade the display area AA.

Accordingly, in another embodiment of the present disclosure, the organic material layer that serves as a moisture or oxygen invasion path in both of the first direction (X-axis direction) and the second direction (Y-axis direction) is broken, thereby preventing moisture or oxygen from penetrating into the display area AA. This will be described with reference to the drawings.

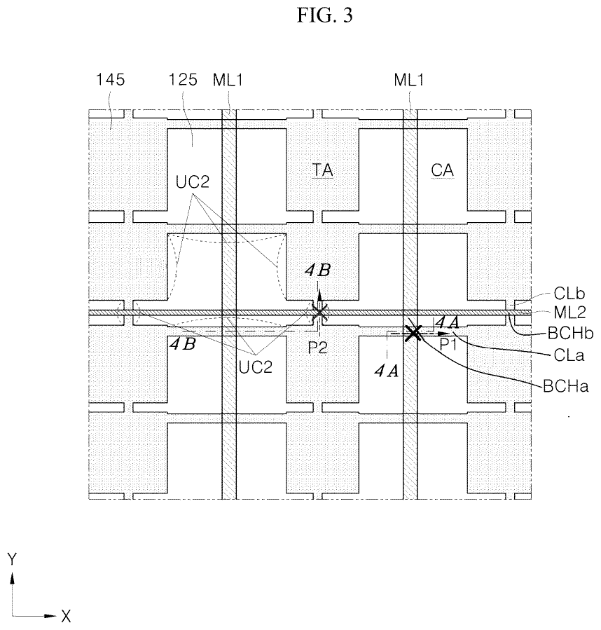

FIG. 3 is an enlarged plan view showing a portion of a non-pad area according to another embodiment of the present disclosure. For example, FIG. 3 is an enlarged plan view of a portion 3 in FIG. 1. For convenience of illustration, FIG. 3 shows (i) an organic material layer 145 disposed in the transmissive area TA, and (ii) an overcoat layer 125, a first wiring line ML1 and a second wiring line ML2 disposed in a circuit area CA, without illustrating various other components disposed in the non-pad area NPAD.

Referring to FIG. 1 and FIG. 3, the non-pad area NPAD may include a plurality of transmissive areas TA and a plurality of circuit areas CA. To this end, the transmissive area TA may be an area in which an opaque material or a reflective material is not disposed. In addition, various circuit elements may be disposed in the circuit area CA. The display device according to an example embodiment of the present disclosure may secure transmittance in the transmissive area TA. Thus, the display device may act as a transparent display device in which an object disposed in rear of the display panel PNL may be recognized by the user located in front of the display panel PNL.

The transmissive area TA may be an area where the organic material layer 145 is disposed. Adjacent ones of the plurality of transmissive areas TA may be spaced apart from each other while the circuit area CA is interposed therebetween. For convenience of illustration, the organic material layer 145 is shown as being disposed only in the transmissive area TA. However, the organic material layer 145 may be disposed across an entire surface of the display device. Accordingly, the organic material layer 145 may be disposed on top of the overcoat layer 125 of the circuit area CA.

Connection lines CLa and CLb may be formed between adjacent transmissive areas TA due to the presence of the undercut structure UC. For example, when the transmissive area TA is surrounded only with the overcoat layer OC, moisture may penetrate into the display area through the organic material layer. To prevent this situation, the undercut structure UC is disposed under the overcoat layer OC to break the organic material layer such that the connection lines CLa and CLb may be created. The connection lines CLa and CLb may include the first connection line CLa and the second connection line CLb. The first connection line CLa may be disposed between transmissive areas TA adjacent to each other in the first direction, and the second connection line CLb may be disposed between transmissive areas TA adjacent to each other in the second direction different from the first direction. In this regard, the first direction may be the X-axis direction, and the second direction may be the Y-axis direction. Moreover, the first direction may be a row direction, and the second direction may be a column direction. The first connection line CLa and the second connection line CLb may include the same material as that of the organic material layer 145.

In one or more examples, each of the first connection line CLa and the second connection line CLb may include (or may be) an organic material layer that is the same as the organic material layer 145. In one or more examples, the first connection line CLa and the second connection line CLb may be formed at the same time (or at the same processing step) as that of the organic material layer 145. In one or more other examples, the first connection line CLa and the second connection line CLb may be formed at a time (or at a processing step) different from that of the organic material layer 145. In one or more examples, the first connection line CLa may extend along the same direction as the second writing line ML2. In one or more examples, the second connection line CLb may extend along the same direction as the first writing line ML1.

The first connection line CLa may be disposed between and connected to transmissive areas TA arranged in the first direction. The second connection line CLb may be disposed between and connected to transmissive areas TA arranged in the second direction different from the first direction. Accordingly, moisture may penetrate into the display area AA along the direction in which the first connection line CLa or the second connection line CLa extends. In other words, through a first moisture penetrating path P1 where the first connection line CLa is disposed, a second moisture penetrating path P2 where the second connection line CLb is disposed, and a third moisture penetrating path P3 extending in a direction in which a side of the transmissive area TA extends, the moisture may penetrate the display area.

In one or more examples, as the first connection line CLa extends along the first direction (e.g., the X-axis direction). The undercut structure UC is disposed on each of both opposing sides (one side and the other side) in the second direction (e.g., Y-axis direction) of the first connection line CLa extending in the first direction. Accordingly, the undercut structure UC breaks the first connection line CLa separates (or divides) the overcoat layer 125 into portions arranged so as to be spaced from each other in the second direction (e.g., the Y-axis direction). In one or more examples, the first connection line CLa may act as a moisture barrier to prevent the moisture from flowing in the second direction (e.g., Y-axis direction). Accordingly, the undercut structure UC located on one side and the other side of the first connection line CLa may prevent the moisture from flowing from the overcoat layer 125 located at one side of the first connection line CLa to the overcoat layer 125 located at the other side of the first connection line CLa. However, in these examples, the first connection line CLa itself does not (and cannot) block moisture from moving along the first direction (e.g., the X-axis direction), as the first connection line CLa itself extends along the first direction (e.g., the X-axis direction).

Further, in one or more examples, as the second connection line CLb extends along the second direction (e.g., the Y-axis direction). The undercut structure UC is disposed on each of both opposing sides (one side and the other side) in the first direction (e.g., X-axis direction) of the second connection line CLb extending in the second direction (e.g., the Y-axis direction). Accordingly, the undercut structure UC separates (or divides) the overcoat layer 125 in the first direction (e.g., the X-axis direction). Hence, the second connection line CLb may act as a moisture barrier and may block (or prevent) moisture from moving along the first direction (e.g., the X-axis direction). Thus, the undercut structure UC may block the movement of moisture from the overcoat layer 125 located at one side of the second connection line CLb (e.g., located at the left side or the right side of CLb) to the overcoat layer 125 located at the other side of the second connection line CLb (e.g., located at the right side or the left side of CLb, respectively). However, in these examples, the second connection line CLb itself does not (and cannot) block moisture from moving along the second direction (e.g., the Y-axis direction), as the second connection line CLb itself extends along the second direction (e.g., the Y-axis direction).

To solve the foregoing problems, in one or more examples of the present disclosure, the moisture penetrating paths P1 and P2 (in connection with the organic material layer 145, the first connection line CLa, and the second connection line CLb disposed in the transmissive area TA or the circuit area CA) may be prevented from being formed.

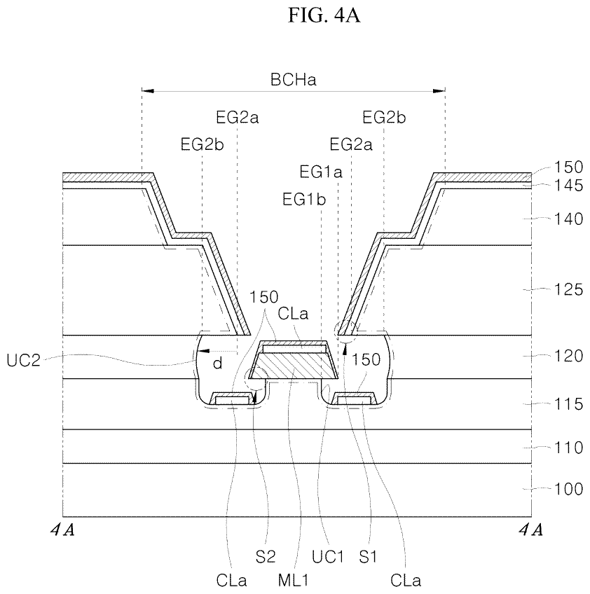

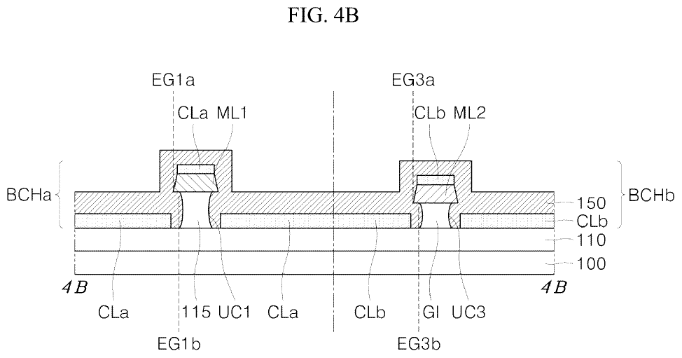

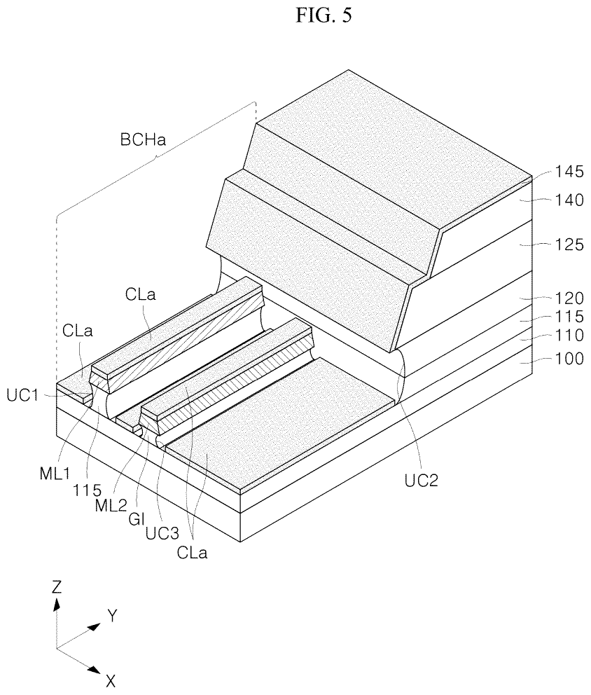

Further details are described below with reference to FIG. 4A to FIG. 5.

FIG. 4A and FIG. 4B are examples of diagrams respectively showing certain portions of the structure depicted in FIG. 3. In this regard, FIG. 4A shows an example of composite cross sectional views taken along a line 4A in FIG. 3. In this regard, FIG. 4A may be viewed as a composite illustration of a cross-sectional view of the first connection line CLa (located at the left side of the first wiring line ML1), a cross-sectional view of the first wiring line ML1, and a cross-sectional view of the first connection line CLa (located at the right side of the first wiring line ML1), along with cross-sectional views of other layers.

FIG. 4B shows an example of a cross-sectional view taken along a line 4B in FIG. 3. FIG. 5 shows an example of a schematic perspective view according to another embodiment of FIG. 3. In this regard, FIG. 5 shows a configuration in which the first wiring line ML1 and the second wiring line ML2 are spaced apart from each other in the first direction (X-axis direction) and extend along the second direction (Y-axis direction).

Referring to FIG. 4A and FIG. 4B together with FIG. 1, a first wiring line ML1 and the second wiring line ML2 may be disposed in the non-pad area NPAD. The first wiring line ML1 may be disposed in the circuit area CA and may extend along the second direction of the display panel PNL. The second wiring line ML2 may be disposed in the circuit area CA, and the second wiring line ML2 may extend along the first direction intersecting the second direction. In this regard, the first direction may be an X-axis direction, and the second direction may be a Y-axis direction. However, the present disclosure is not limited thereto. For example, the first direction may be a longitudinal direction, and the second direction may be a transverse direction.

Referring to FIG. 5, in another embodiment, the first wiring line ML1 may extend along the second direction (Y-axis direction) of the display panel PNL. The second wiring line ML2 may extend along the second direction (Y-axis direction) in which the first wiring line ML1 extends.

The first wiring line ML1 and the second wiring line ML2 may be disposed in different layers. For example, the second wiring line ML2 may be disposed under the first wiring line ML1 which may be disposed above the second wiring line ML2. A multi-layer insulating stack may be disposed between the first wiring line ML1 and the second wiring line ML2.

Each of the first wiring line ML1 and the second wiring line ML2 may be a wiring line extending from the display area AA. For example, the first wiring line ML1 may be a source/drain wiring line extending to the non-pad area NPAD while constituting (or including, or being, or being connected to) a source electrode or a drain electrode in the display area AA. The second wiring line ML2 may be a gate wiring line extending to the non-pad area NPAD while constituting (or including, or being, or being connected to) a gate electrode in the display area AA.

Each of the first wiring line ML1 and the second wiring line ML2 disposed in the non-pad area NPA may be in a floating state in which each of the first wiring line ML1 and the second wiring line ML2 is not electrically connected to the source/drain electrode or the gate electrode disposed in the display area AA. In other words, each of the first wiring line ML1 and the second wiring line ML2 is not electrically connected to a second electrode 150, and thus does not affect an operation of the display device.

The first wiring line ML1 may extend so as to intersect the first connection line CLa disposed between transmissive areas TA arranged in the first direction. The second wiring line ML2 may extend so as to intersect the second connection line CLb disposed between transmissive areas TA arranged in the second direction.

Each of undercut structures UC1 and UC3 may be disposed under a corresponding one of the first wiring line ML1 and the second wiring line ML2. An undercut structure UC2 may be disposed under an overcoat layer 125 of the circuit area CA. The undercut structures UC1, UC2, and UC3 may include the first undercut structure UC1, the second undercut structure UC2, and the third undercut structure UC3. Each of the undercut structures UC1, UC2, and UC3 may break (or split or divide) a corresponding one of the first connection line CLa, the organic material layer 145, and the second connection line CLb from each other to prevent the first and second moisture penetrating paths P1 and P2 from being formed. The undercut structures UC1, UC2, and UC3 may be disposed in different layers, for example.

In one embodiment of the present disclosure, for example, the first wiring line ML1 may include the first undercut structure UC1 (disposed between the transmissive areas TA arranged along the X-axis as the first direction), and the second undercut structure UC2 (disposed in a different layer from a layer in which the first undercut structure UC1 is disposed). Thus, the organic material layer 145 and the first connection line CLa may be discontinuous, and thus the organic material layer 145 and the first connection line CLa may be disconnected from each other such that the first moisture penetrating path P1 may be prevented from being formed. Further details are below with reference to FIG. 4A.

Referring to FIG. 4A, in the non-pad area NPAD and on the substrate 100, a buffer layer 110, an interlayer insulating layer 115, the first wiring line ML1, a protective film 120, an overcoat layer 125, a bank 140, an organic material layer 145, and a second electrode 150 may be disposed. Moreover, although not shown in the drawing for convenience of illustration, an encapsulation layer that seals the underlying structures may be disposed on top of the second electrode 150.

Each of the buffer layer 110 and the interlayer insulating layer 115 may be made of an insulating material, and may have a single-layer or multi-layer structure. The interlayer insulating layer 115 may be formed so as to extend to the non-pad area NPAD while covering a gate electrode of the thin film transistor in the display area AA.

The first wiring line ML1 may be disposed on the interlayer insulating layer 115. The first wiring line ML1 may be, for example, a source/drain wiring line extending to the non-pad area NPAD while constituting a source electrode or a drain electrode in the display area AA. The first wiring line ML1 may be provided with the first undercut structure UC1 disposed thereunder.

The first undercut structure UC1 may have an undercut shape with respect to the interlayer insulating layer 115. The undercut may refer to a phenomenon in which a portion of the interlayer insulating layer 115 disposed under the first wiring line ML1 is additionally removed. In other words, an end of the first undercut structure UC1 is not aligned with an end EG1a of the first wiring line ML1, and is formed by additionally removing a portion of the interlayer insulating layer 115 disposed under the first wiring line ML1 by a predetermined distance (or depth) inwardly of the end EG1a of the first wiring line ML1.

Accordingly, each of both (or two) opposing ends EG1a of the first wiring line ML1 protrudes outwardly beyond an end EG1b of the interlayer insulating layer 115 in which the first undercut structure UC1 positioned under the first wiring line ML1 is disposed.

The protective film 120 may be disposed on the interlayer insulating layer 115 in which the first undercut structure UC1 is disposed. The overcoat layer 125 may be disposed on the protective film 120. The protective film 120 may include an insulating film made of an oxide. The overcoat layer 125 may planarize a step caused by various circuit elements disposed in the circuit area CA. The overcoat layer 125 may include a photoactive compound (PAC).

The overcoat layer 125 may be provided with the second undercut structure UC2 disposed thereunder. The second undercut structure UC2 may be formed by additionally removing a portion of each of the protective film 120 and the interlayer insulating layer 115 disposed under the overcoat layer 125. The second undercut structure UC2 may be formed by additionally removing a portion of the protective film 120 by a predetermined distance d (or depth) inwardly of an end EG2a of the overcoat layer 125. Accordingly, the end EG2a of the overcoat layer 125 may have a shape protruding outwardly beyond an end EG2b of the protective film 120 disposed thereunder.

The second undercut structure UC2 may be formed by performing a dry etching process and then a wet etching process using a wet solution. The wet solution may include a buffered oxide etchant (BOE). The wet solution may penetrate into the protective film 120 including the oxide and may selectively remove only the protective film 120 without affecting other components such as the overcoat layer 125 to form the second undercut structure UC2.

The bank 140 may be disposed on the overcoat layer 125. On the bank 140 and in the non-pad area NPAD, the organic material layer 145 and the second electrode 150 may be sequentially disposed.

The organic material layer 145 may be disposed along an entire area of the display panel PNL and in the display area AA and the non-pad area NPAD. Accordingly, the organic material layer 145 may extend along and on an upper surface and a side surface of the bank 140 and a side surface of the overcoat layer 125. The organic material layer 145 extends along the side surface of the overcoat layer 125. In this regard, the organic material layer 145 may be broken S2 (or separated or split or severed or disconnected or divided) at the end EG2a of the overcoat layer 125 having a shape protruding outwardly beyond the end EG2b of the protective film 120 due to the second undercut structure UC2.

Moreover, the first connection line CLa and the second connection line CLb connecting adjacent transmissive areas TA to each other may be patterned together with the organic material layer 145. The first connection line CLa (which includes or is an organic material layer that is the same as the organic material layer 145) may be disposed on an upper surface of the first wiring line ML1. In this regard, the organic material layer 145 may be broken S2 (or separated, split or severed or disconnected) at the end EG1a of the overcoat layer 125 having a shape protruding outwardly beyond the end EG1b of the interlayer insulating layer 115 due to the first undercut structure UC1.

Accordingly, the organic material layer 145 and the first connection line CLa may be broken S1 and S2 due to the second undercut structure UC2 and the first undercut structure UC1, respectively, thereby preventing the first moisture penetrating path P1 from being created.

Referring back to FIG. 3, a display device of one or more example embodiments of the present disclosure may include a plurality of blocking channels, such as first and second blocking channels BCHa and BCHb. Each blocking channel may be disposed between adjacent ones of the plurality of transmissive areas TA. The first blocking channel BCHa may be disposed between transmissive areas arranged in the first direction (e.g., an X-axis direction) among the plurality of transmissive areas TA. The second blocking channel BCHb may be disposed between transmissive areas arranged in the second direction (e.g., a Y-axis direction) among the plurality of transmissive areas TA. The first connection line CLa (or at least a portion thereof) and the second connection line CLb (or at least portions thereof) may be disposed at the first blocking channel BCHa and the second blocking channel BCHb, respectively. Each of the wiring lines ML1 and ML2 (or portions thereof) may extend so as to intersect a corresponding one of the plurality of blocking channels. For example, the wiring line ML1 and the wiring line ML2 may extend so as to intersect the first blocking channel BCHa and the second blocking channel BCHb, respectively. The first and second blocking channels BCHa and BCHb may be utilized to block the movement of moisture across and/or along the respective blocking channels BCHa and BCHb. In one or more examples, the first and second blocking channels BCHa and BCHb may be utilized to block the moisture penetration paths (e.g., P1 and P2, respectively) from being formed.

With reference to FIG. 4A, a first blocking channel BCHa is illustrated according to one or more example embodiments of the present disclosure is shown. In FIG. 3, the dot-dash line illustrates an edge(s) or an outline(s) of a first blocking channel BCHa. In one or more examples, side surfaces of the bank 140 and the overcoat layer 125 may be disposed at the first blocking channel BCHa or may form an edge(s) of the first blocking channel BCHa. The first and second undercut structures UC1 and UC2 may be disposed at the first blocking channel BCHa or may form an edge(s) of the first blocking channel BCHa. The first wiring line ML1, the first connection line CLa, and the second electrode 150 (e.g., the second electrode 150 on the first connection line CLa) may be disposed at (or in or on) the first blocking channel BCHa or may be disposed at (or in or on) a lower portion of the first blocking channel BCHa. The second electrode 150 may also be disposed on the organic material layer 145, which is disposed on the side surfaces of the bank 140 and the overcoat layer 125. Thus, the second electrode 150 and the organic material layer 145 may be disposed at (or in or on) the first blocking channel BCHa or may be disposed at (or in or on) an upper portion of the first blocking channel BCHa.

Examples of a first blocking channel BCHa and a second blocking channel BCHb are also illustrated with reference to FIG. 4B. As shown on the left side of FIG. 4B, the first wiring line ML1, the first connection line CLa (or a middle portion and two opposing portions of the first connection line CLa), and the second electrode 150 may be disposed at (or in or on) the first blocking channel BCHa. The first undercut structure UC1 may be disposed at the first blocking channel BCHa or may form an edge(s) of the first blocking channel BCHa. As shown on the right side of FIG. 4B, the second wiring line ML2, the second connection line CLb (or a middle portion and two opposing portions of the second connection line CLb), and the second electrode 150 may be disposed at (or in or on) the second blocking channel BCHb. The third undercut structure UC3 may be disposed at the second blocking channel BCHb or may form an edge(s) of the second blocking channel BCHb.

Moreover, in one embodiment of the present disclosure, for example, the second wiring line ML2 with the third undercut structure UC3 disposed thereunder may be disposed between the transmissive areas TA arranged in the Y-axis which is the second direction, and the organic material layer 145 and the second connection line CLb may be broken (or separated or split or severed or disconnected or divided) such that the occurrence of the second moisture penetrating path P2 may be prevented. Further details are described below with reference to FIG. 3 to FIG. 5.

Referring to FIG. 3 to FIG. 5, on the substrate 100 and in the circuit area CA, the buffer layer 110, a gate insulating layer GI, the second wiring line ML2, the interlayer insulating layer 115, the first wiring line ML1, the organic material layer 145 and the second electrode 150 may be sequentially stacked and disposed. In one or more examples, on the substrate 100 and in the circuit area CA, the buffer layer 110, the interlayer insulating layer 115, the first wiring line ML1, the first connection line CLa, and the second electrode 150 may be sequentially stacked and disposed. In one or more examples, on the substrate 100 and in the circuit area CA, the buffer layer 110, the gate insulating layer GI, the second wiring line ML2, the second connection line CLb and the second electrode 150 may be sequentially stacked and disposed. In FIG. 5, the second electrode 150 is not shown for convenience of illustration.

As shown in FIG. 4A, in an area in which the first wiring line ML1 is disposed under the first connection line CLa disposed between transmissive areas TA arranged in the first direction and in which the first wiring line ML1 extending in the second direction that intersects the first connection line CLa is disposed, the end EG1a of the first wiring line ML1 has a shape protruding outwardly beyond the end EG1b of the interlayer insulating layer 115 due to the first undercut structure UC1. Accordingly, the first connection line CLa may be broken (or divided) into a first portion disposed on the upper surface of the first wiring line ML1 and a second portion disposed at each of both (or at least two) opposing sides of the first wiring line ML1 and on the upper surface of the buffer layer 110, while the first undercut structure UC1 is formed between the first and second portions. In this regard, in one or more examples, the first connection line CLa may be broken (or divided) into the first portion and at least two second portions. Each of the at least two second portions of the first connection line CLa may be disposed at (or in) an area that is next to (or adjacent to) a corresponding side surface of the first wiring line ML1. Moreover, the organic material layer 145 may be broken and the first connection line CLa may be disconnected from the organic material layer 145 due to the second undercut structure UC2 disposed under the overcoat layer 125 and disposed (at least partially or entirely) above the first connection line CLa. As the organic material layer 145 and the first connection line CLa are broken due to the second undercut structure UC2 and the first undercut structure UC1, respectively, occurrence of the first moisture penetrating path P1 extending in the first direction may be prevented.

Moreover, as shown in FIG. 4B, in an area in which the second wiring line ML2 is disposed under the second connection line CLb disposed between transmissive areas TA arranged in the second direction and in which the second wiring line ML2 extending in the first direction intersecting the second connection line CLb is disposed, an end EG3a of the second wiring line ML2 protrudes outwards beyond an end EG3b of the gate insulating layer GI due to the third undercut structure UC3.

Accordingly, the second connection line CLb may be broken (or divided) into a first portion disposed on an upper surface of the second wiring line ML2 and a second portion disposed at each of both (or at least two) opposing sides of the second wiring line ML2 and disposed on the upper surface of the buffer layer 110 while the third undercut structure UC3 is disposed between the first and second portions. Thus, the occurrence of the second moisture penetrating path P2 may be prevented. The second wiring line ML2 may be a gate wiring line extending to the non-pad area NPAD while constituting (or including, or being, or being connected to) a gate electrode in the display area AA. However, the present disclosure is not limited thereto.

Moreover, the second electrode 150 disposed on the first connection line CLa and the second connection line CLb may continuously extend. The second electrode 150 may be used as an auxiliary electrode, for example.

Moreover, as shown in FIG. 5, the first wiring line ML1 may extend along the second direction (the Y-axis direction) of the display panel PNL. The second wiring line ML2 may extend in the second direction (the Y-axis direction) in the same direction as the direction in which the first wiring line ML1 extends. In the area where the first wiring line ML1 is disposed under the first connection line CLa disposed between the transmissive areas TA arranged in the first direction, and extends in the second direction, a side end of the first wiring line ML1 protrudes beyond a side end of the interlayer insulating layer 115 due to the first undercut structure UC1. Accordingly, the first connection line CLa may be broken (divided) into the first portion disposed on the upper surface of the first wiring line ML1 and the second portion disposed on each of both opposing sides of the first wiring line ML1, wherein the first and second portions are spaced from each other while the first undercut structure UC1 is formed between the first and second portions.

Moreover, the second wiring line ML2 may be disposed so as to be spaced apart from the first wiring line ML1 in the first (X-axis) direction. In an area where the second wiring line ML2 located in a different layer from a layer in which the first wiring line ML1 is disposed is disposed, a side end of the second wiring line ML2 protrudes beyond a side end of the gate insulating layer GI due to the third undercut structure UC3. Thus, the first connection line CLa may be broken (divided) into the first portion disposed on the upper surface of the first wiring line ML1 and the second portion disposed on each of both opposing sides of the first wiring line ML1, wherein the first and second portions are spaced from each other while the third undercut structure UC3 is formed between the first and second portions.

Accordingly, the first connection line CLa may be broken into the portions spaced from each other while each of the first undercut structure UC1 and the third undercut structure UC3 disposed on the different layers is disposed between adjacent ones of the portions, thereby preventing the first moisture invasion path P1 from being formed. According to the configuration in FIG. 5, the blocking channel used to block the flow of moisture may correspond to the first blocking channel BCHa. The second wiring line ML2 may be a gate wiring line extending to the non-pad area NPAD while constituting the gate electrode in the display area AA. However, embodiments of the present disclosure are not limited thereto.

Referring to FIG. 3 and FIG. 5, each undercut structure may overlap each moisture penetrating path in a vertical direction. For example, the second undercut structure UC2 disposed under the overcoat layer 125 may vertically overlap the organic material layer 145 disposed in the transmissive areas TA arranged in each of the first direction and the second direction. Accordingly, the second undercut structure UC2 may be defined by at least three side surfaces of the circuit area CA facing at least three corresponding side surfaces of the transmissive area TA.

The first wiring line ML1 and the second wiring line ML2 may be disposed in different layers. For example, the second wiring line ML2 may be disposed under the first wiring line ML1 which may be disposed above the second wiring line ML2. Accordingly, due to the first undercut structure UC1 disposed under the first wiring line ML1 and the third undercut structure UC3 disposed under the second wiring line ML2, the first connection line CLa and the second connection line CLb may be broken (or split or divided) respectively, such that the moisture penetrating paths that may occur in the first or second direction may be blocked using the multilayer structure.

Breaking the organic material layer serving as a moisture penetrating path in the non-pad area NPAD using the multiple layer structure composed of the undercut structures vertically overlapping the moisture penetrating path direction may allow the moisture penetration to the display area to be blocked. Accordingly, the lifespan of the organic light-emitting element disposed in the display area may be extended, and the display device may operate using lower power. Thus, the performance and lifespan of the organic light-emitting element may be secured for a longer period and thus, the quality of image in the display device may be secured at a low power level, thereby reducing power consumption.

In one example, introducing the same array structure as that in the display area AA into the non-pad area NPAD in the display device that can be cut may allow convenience of the process step to be improved. Further details are provided with reference to the drawings described below.

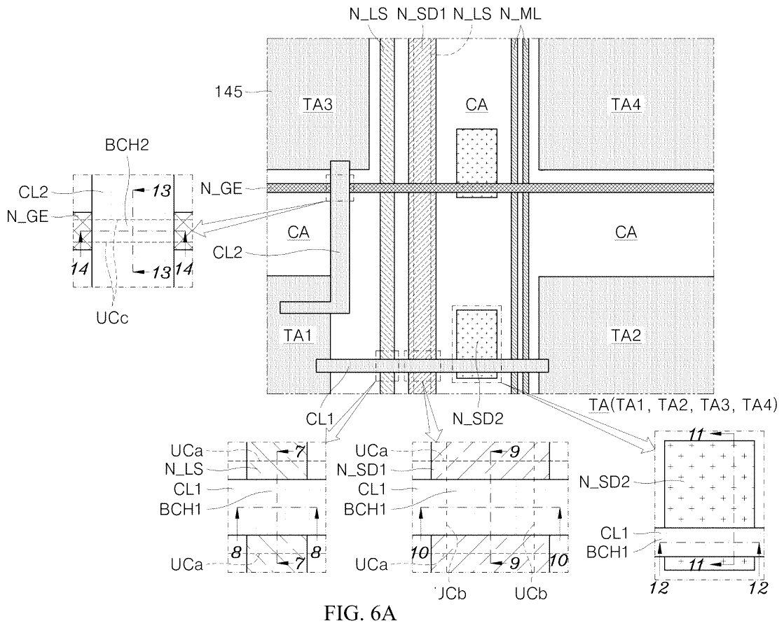

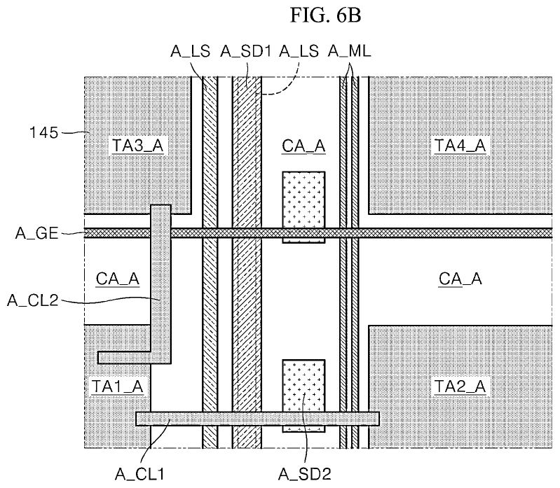

FIG. 6A is an enlarged plan view showing a portion of a non-pad area according to another embodiment of the present disclosure. FIG. 6B is an enlarged plan view showing a portion of a display area according to another embodiment of the present disclosure. For example, FIG. 6A is an enlarged plan view of an area 6A in FIG. 1. FIG. 6B is an enlarged plan view of an area 6B in FIG. 1.

Referring to FIG. 6A and FIG. 6B, the non-pad area NPAD may include a plurality of transmissive areas TA and a plurality of circuit areas CA. For example, the plurality of transmissive areas TA may include a first transmissive area TA1, a second transmissive area TA2, a third transmissive area TA3, and a fourth transmissive area TA4. In this regard, the first transmissive area TA1, and the second transmissive area TA2 may be spaced apart from each other in the first direction, while the third transmissive area TA3 and the fourth transmissive area TA4 may be spaced apart from each other in the first direction. Moreover, the first transmissive area TA1 and the third transmissive area TA3 may be spaced apart from each other in the second direction while the second transmissive area TA2 and the fourth transmissive area TA4 may be spaced apart from each other in the second direction.

Each of connection lines CL1 and CL2 may be disposed between and connected to adjacent transmissive areas TA. The connection lines CL1 and CL2 may include the first connection line CL1 disposed between and connected to the first transmissive area TA1 and the second transmissive area TA2 arranged in the first direction, and the second connection line CL2 disposed between and connected to the first transmissive area TA1 and the third transmissive area TA3 arranged in the second direction. In this regard, the first direction may be an X-axis direction and the second direction may be a Y-axis direction. However, the present disclosure is not limited thereto. For example, the first direction may be a longitudinal direction or a first horizontal direction, while the second direction may be a transverse direction or a second horizontal direction.

In the circuit area CA of the non-pad area NPAD, a plurality of signal wiring lines extending from the display area AA may be disposed. For example, the plurality of signal wiring lines may include a light-blocking layer line N_LS, source/drain lines N_SD1 and N_SD2, a gate electrode line N_GE, and a driving signal transmission line N_ML.

In one or more examples, each of the first connection line CLa and the second connection line CLb may include (or may be) an organic material layer that is the same as the organic material layer 145. In one or more examples, the first connection line CLa and the second connection line CLb may be formed at the same time (or at the same processing step) as that of the organic material layer 145. In one or more other examples, the first connection line CLa and the second connection line CLb may be formed at a time (or at a processing step) different from that of the organic material layer 145. In one or more examples, the first connection line CLa may extend substantially along the same direction as the second wiring line ML2 such as the gate electrode line N_GE. In one or more examples, the second connection line CLb may extend substantially along the same direction as the first wiring line ML1 such as the light-blocking layer line N_LS, the source/drain lines N_SD1 and N_SD2, and/or the driving signal transmission line N_ML.

The plurality of transmissive areas TA1, TA2, TA3, and TA4, and the circuit area CA of the non-pad area NPAD may have an array structure, which may correspond to (may be similar to) an array structure of a plurality of transmissive areas TA1_A, TA2_A, TA3_A, TA4_A, and a circuit area CA_A of the display area AA.

For example, the light-blocking layer line N_LS of the non-pad area NPAD may extend to the non-pad area NPAD while constituting a light-blocking layer A_LS in the display area AA. The source/drain lines N_SD1 and N_SD2 of the non-pad area NPAD may extend to the non-pad area NPAD while constituting source/drain electrodes A_SD1 and A_SD2 in the display area AA. The source/drain lines N_SD1 and N_SD2 may include the first source/drain line N_SD1 and the second source/drain line N_SD2. Moreover, the gate electrode line N_GE of the non-pad area NPAD may extend to the non-pad area NPAD while constituting a gate electrode A_GE in the display area AA. The driving signal transmission line N_ML of the non-pad area NPAD may extend from each of various signal transmission lines A_ML disposed in the display area AA. For example, the various signal transmission lines may include a high potential voltage line, a low potential voltage line, a data line, and a reference voltage line. However, the present disclosure is not limited thereto. Further, in the display area AA, each of connection lines A_CL1 and A CL2 may be disposed between and connected to adjacent ones of the transmissive areas TA1_A, TA2_A, TA3_A, and TA4_A.

The light-blocking layer line N_LS and the first and second source/drain lines N_SD1 and N_SD2 may extend so as to intersect the first connection line CL1. Unlike the plurality of signal wiring lines disposed in the display area AA, the plurality of signal wiring lines disposed in the non-pad area NPAD may be in a floating state and thus may not be electrically connected to another wiring line. For example, the plurality of signal wiring lines disposed in the display area AA may be electrically connected to a wiring line (such as a high-potential voltage line or a low-potential voltage line) that supplies an electrical signal or voltage. On the contrary, the plurality of signal wiring lines disposed in the non-pad area NPAD may not be electrically connected to the wiring that supplies the electrical signal or voltage.

The same array structure as that of the display area AA may be disposed in the non-pad area NPAD such that convenience in the process step may be improved. For example, in order to form the plurality of signal wiring lines, having shapes different from shapes of those of the display area AA, in the non-pad area NPAD, a separate process step is typically required. However, in the display device according to another embodiment of the present disclosure, while the plurality of signal wiring lines of the same shapes as the shapes of those in the non-pad area NPAD are formed in the display area AA, the plurality of signal wiring lines of the same shapes as the shapes of those in the display area AA are formed in the non-pad area NPAD. Thus, the process step does not have to be changed, such that the convenience of the process step may be improved. In other words, the plurality of transmissive areas TA and the circuit area CA of the non-pad area NPAD may have the same array structure as the array structure of the plurality of transmissive area TA and circuit area CA of the display area AA.

Moreover, the same array structure as that of the display area AA may be disposed in the non-pad area NPAD, such that the undercut structures respectively disposed under the plurality of signal wiring lines disposed in different layers are disposed in different layers to form a multi-layered structure. Thus, the occurrence of the moisture penetrating path may be prevented due to the multiple layer structure.

Referring to FIG. 6A, a plurality of blocking channels, such as first and second blocking channels BCH1 and BCH2, may be provided. Each blocking channel may be disposed between adjacent ones of the plurality of transmissive areas TA. The first blocking channel BCH1 may be disposed between transmissive areas arranged in the first direction (e.g., an X-axis direction) among the plurality of transmissive areas TA. The second blocking channel BCH2 may be disposed between transmissive areas arranged in the second direction (e.g., a Y-axis direction) among the plurality of transmissive areas TA. The first connection line CL1 and the second connection line CL2 (or at least portions thereof) may be disposed at the first blocking channel BCH1 and the second blocking channel BCH2, respectively. The light-blocking layer line N_LS, the source/drain lines N_SD1, and N_SD2, and the driving signal transmission line N_ML (or portions thereof) may extend so as to intersect the first blocking channel BCH1 (or the respective portions of the first blocking channel BCH1). The gate electrode line N_GE (or a portion thereof) may extend so as to intersect the second blocking channel BCH2 (or a portion of the second blocking channel BCH2). The first and second blocking channels BCH1 and BCH2 may be utilized to block the movement of moisture across and/or along the respective blocking channels BCH1 and BCH2. In one or more examples, the first and second blocking channels BCH1 and BCH2 may be utilized to block moisture penetration paths from being formed.

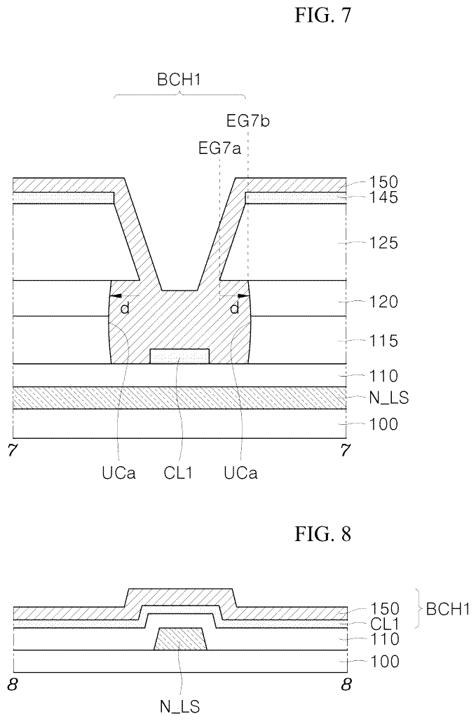

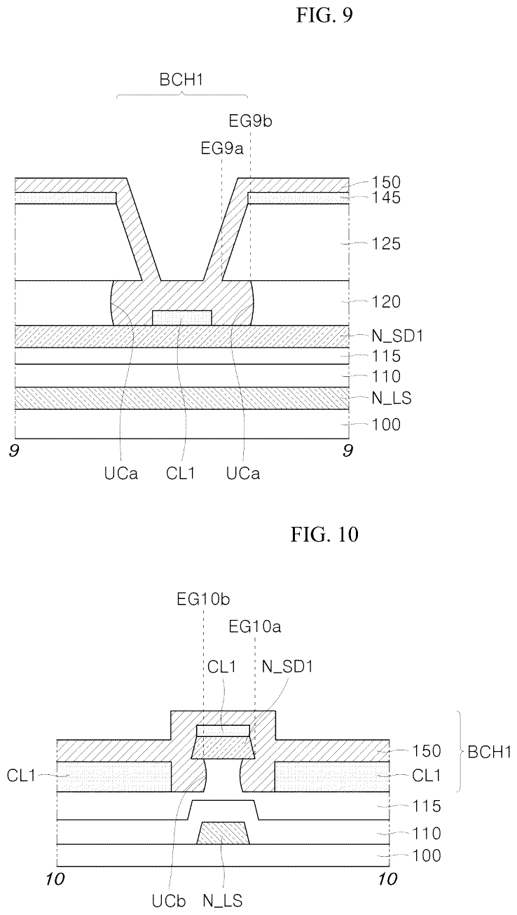

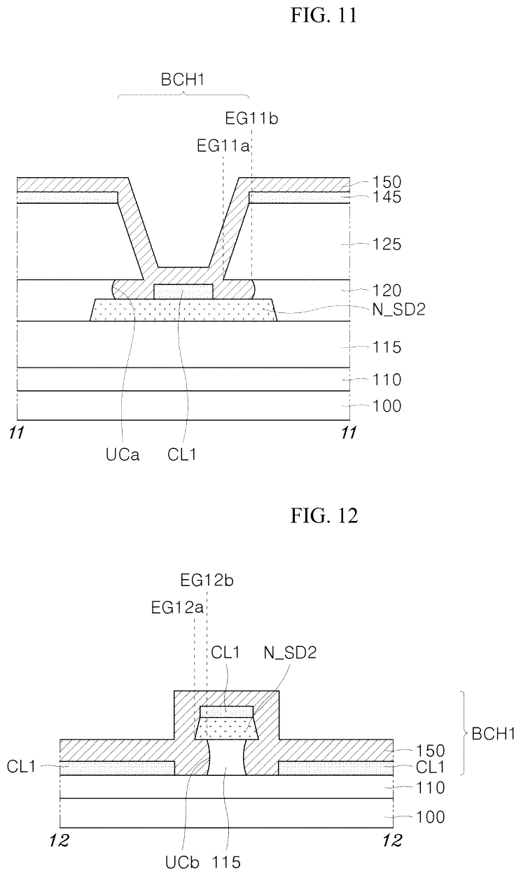

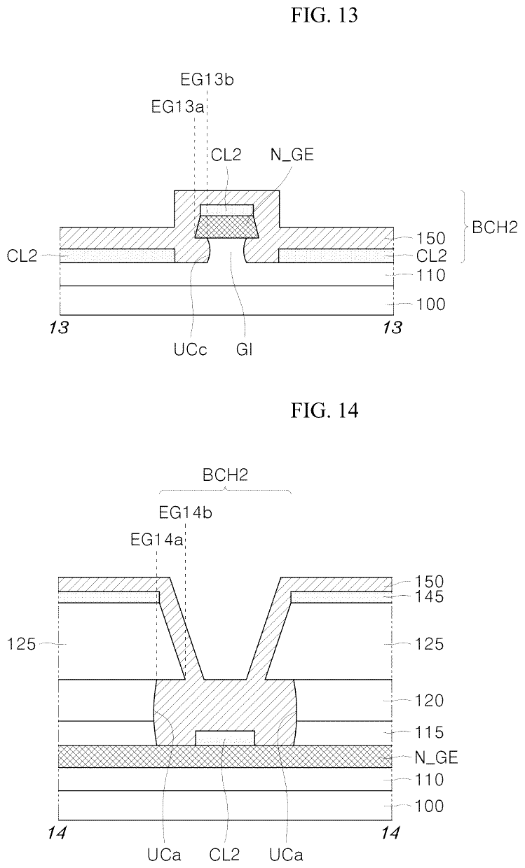

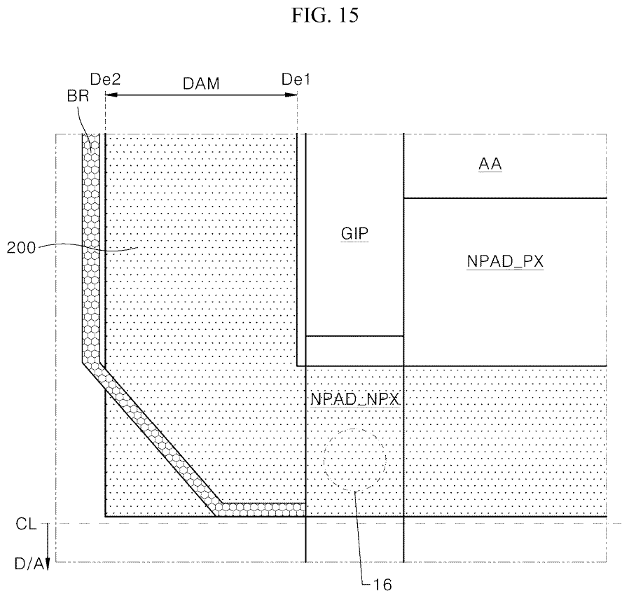

FIG. 7 to FIG. 14 are example views showing cross sections of certain respective portions of the views depicted in FIG. 6A and FIG. 6B. In this regard, FIG. 7 and FIG. 8 are respectively examples of cross-sectional views in the longitudinal and transverse directions of a portion where the light-blocking layer line N_LS is disposed. In particular, FIG. 7 illustrates an example of a cross-sectional view taken along a line 7-7 in FIG. 6A, and FIG. 8 illustrates an example of a cross-sectional view taken along a line 8-8 in FIG. 6A. FIG. 9 illustrates an example of a cross-sectional view taken along a line 9-9 in FIG. 6A, and FIG. 10 illustrates an example of a cross-sectional view taken along a line 10-10 in FIG. 6A. FIG. 11 illustrates an example of a cross-sectional view taken along a line 11-11 in FIG. 6A, and FIG. 12 illustrates an example of a cross-sectional view taken along a line 12-12 in FIG. 6A. FIG. 13 illustrates an example of a cross-sectional view taken along a line 13-13 in FIG. 6A, and FIG. 14 illustrates an example of a cross-sectional view taken along a line 14-14 in FIG. 6A. FIG. 17 is an example of a perspective view for illustrating a configuration in which the moisture invasion path is blocked by a multi-layer structure. In FIG. 17, the second electrode 150 is not shown for convenience of illustration.

Referring to FIG. 7 and FIG. 8 together with FIG. 6A and FIG. 6B, the first connection line CL1 may be disposed between and connected to the first transmissive area TA1 and the second transmissive area TA2 spaced apart from each other in the first direction. The light-blocking layer line N_LS may extend so as to intersect the first connection line CL1. The light-blocking layer line N_LS, the buffer layer 110, the interlayer insulating layer 115, the protective film 120, and the overcoat layer 125 may be disposed on the substrate 100. As the light-blocking layer line N_LS extends to the non-pad area NPAD while constituting the light blocking layer in the display area AA, the light-blocking layer line N_LS may act as the lowermost layer in contact with the substrate 100. Both (or at least two) opposing portions of the overcoat layer 125 may be respectively disposed at or in both (or at least two) opposing sides of the circuit area CA while the first connection line CL1 is interposed between both opposing portions. In this regard, in one or more examples, the overcoat layer 125 may have two opposing portions, and the circuit area CA may have two opposing sides. Each of the two opposing portions of the overcoat layer 125 may be disposed at or in a corresponding one of the two opposing sides of the circuit area CA.

A first undercut structure UCa may be formed under both opposing portions of the overcoat layer 125, respectively. Each of the first undercut structure UCa may have an undercut shape with respect to the protective film 120 and the interlayer insulating layer 115. Accordingly, an end EG7a of each of both opposing portions of the overcoat layer 125 disposed at a corresponding opposing side of the circuit area with the first connection line CL1 interposed therebetween has a shape protruding outwardly beyond an end EG7b of the protective film 120 and the interlayer insulating layer 115. Then, the organic material layer 145 disposed on the upper surface of the overcoat layer 125 may be broken or discontinuous. The second electrode 150 may be disposed on the first connection line CL1 and an entire area of the organic material layer 145. The second electrode 150 may be used as an auxiliary electrode.

Moreover, referring to FIG. 8, the first connection line CL1 may extend in the longitudinal direction or the first horizontal direction while covering the upper surface of the light-blocking layer line N_LS.

Referring to FIG. 9 and FIG. 10 together with FIG. 6A and FIG. 6B, the first transmissive area TA1 and the second transmissive area TA2 spaced apart from each other in the first direction are interconnected to each other via the first connection line CL1. The light-blocking layer line N_LS may extend so as to intersect the first connection line CL1. On the substrate 100, the light-blocking layer line N_LS, the buffer layer 110, the interlayer insulating layer 115, the first source/drain line N_SD1, the protective film 120, the overcoat layer 125, the organic material layer 145, and the second electrode 150 may be disposed. As the light-blocking layer line N_LS extends to the non-pad area NPAD while constituting the light blocking layer in the display area AA, the light-blocking layer line N_LS may act as the lowermost layer on the substrate 100. The first source/drain line N_SD1 may be positioned above the light-blocking layer line N_LS while the buffer layer 110 and the interlayer insulating layer 115 are interposed therebetween, and may overlap with the light-blocking layer line N_LS.

Both opposing portions of the overcoat layer 125 may be respectively disposed at both opposing sides of the circuit area CA while the first connection line CL1 is interposed therebetween. The first undercut structure UCa may be formed under the overcoat layer 125. The first undercut structure UCa may be disposed (at least partially or entirely) above the first connection line CL1. The first undercut structure UCa may have an undercut shape with respect to the protective film 120. Accordingly, an end EG9a of each of both opposing portions of the overcoat layer 125 disposed at a respective opposing side of the circuit area CA with the first connection line CL1 interposed therebetween protrudes horizontally beyond an end EG9b of the protective film 120. Thus, the organic material layer 145 disposed on the upper surface of the overcoat layer 125 may be broken or discontinuous. The second electrode 150 may be disposed on the first connection line CL1 and the organic material layer 145.

Moreover, the second undercut structure UCb may be formed under the first source/drain line N_SD1, as shown in FIG. 10. The second undercut structure UCb may have an undercut shape with respect to the interlayer insulating layer 115. Accordingly, an end EG10a of the first source/drain line N_SD1 protrudes horizontally beyond an end EG10b of the interlayer insulating layer 115. Thus, the first connection line CL1 on the upper surface of the first source/drain line N_SD1 may be broken or discontinuous. Thus, the first connection line CL1 (or a portion thereof) on the upper surface of the first source/drain line N_SD1 may be isolated (or disconnected or severed) from the first connection line CL1 (or the remaining portion or another portion thereof) disposed on the interlayer insulating layer 115. The second electrode 150 may be disposed on the first connection line CL1 and the organic material layer 145.

Accordingly, as shown in FIG. 17, the organic material layer 145 and the first connection line CL1 may be disconnected from each other in the Y-axis direction or discontinuous due to the first undercut structure UCa disposed in the protective film 120 disposed above the first source/drain line N_SD1. Moreover, the first connection line CL1 may be broken or discontinuous in the X-axis direction due to the second undercut structure UCb disposed under the first source/drain line N_SD1 and defined in the interlayer insulating layer 115 as a different layer from a layer of the protective film 120. In other words, the first connection line CL1 may be broken or discontinuous due to the first and second undercut structures UCa and UCb disposed in different layers, such that the moisture penetrating path may be blocked in both of the first direction (X-axis) direction and the second direction (Y-axis) direction. In this regard, in FIG. 17, only the first source drain line N_SD1 is shown for convenience of illustration. However, the second source drain line N_SD2 may be disposed adjacent to the first source drain line N_SD1 and spaced apart therefrom in the first (X-axis) direction. The first connection line CL1 may be broken or discontinuous due to the first and second undercut structures UCa and UCb disposed in the second source drain line N_SD2 such that the moisture invasion path may be blocked in both of the first direction (X-axis) direction and the second direction (Y-axis) direction.

In other words, the first connection line CL1 extending in the first (X-axis) direction may be broken or discontinuous due to the first and second undercut structures UCa and UCb disposed in different layers, such that the moisture invasion path may be blocked in both of the first direction (X-axis) direction and the second direction (Y-axis) direction.

Referring to FIG. 11 and FIG. 12 together with FIG. 6A and FIG. 6B, the first connection line CL1 is disposed between and connected to the first transmissive area TA1 and the second transmissive area TA2 spaced apart from each other in the first direction. The second source/drain line N_SD2 may extend so as to intersect the first connection line CL1. The second source/drain line N_SD2 and the first source/drain line N_SD1 may be disposed in the same plane (e.g., in, on or at the same layer or may be coplanar with each other.)

The buffer layer 110, the interlayer insulating layer 115, the second source/drain line N_SD2, the protective film 120, the overcoat layer 125, the organic material layer 145, and the second electrode 150 may be disposed on the substrate 100. The second source/drain line N_SD2 may be disposed on the interlayer insulating layer 115.

Both opposing portions of the overcoat layer 125 may be respectively disposed at both opposing sides of the circuit area CA while the first connection line CL1 is interposed therebetween. The first undercut structure UCa may be formed under the overcoat layer 125. The first undercut structure UCa may have an undercut shape with respect to the protective film 120. Accordingly, an end EG11a of each of both opposing portions of the overcoat layer 125 disposed at a corresponding opposing side of the circuit area CA with the first connection line CL1 interposed therebetween may protrude beyond an end EG11b of the protective film 120. Due to this shape, the organic material layer 145 disposed on the upper surface of the overcoat layer 125 may be broken or discontinuous.

Moreover, the organic material layer 145 may be broken or discontinuous due to the first undercut structure UCa disposed in the protective film 120 disposed above the second source/drain line N_SD2. The first connection line CL1 may be broken or discontinuous due to the second undercut structure UCb disposed in the interlayer insulating layer 115 disposed under the second source/drain line N_SD2. In other words, the first connection line CL1 may be broken or discontinuous due to the first undercut structure UCa and the second undercut structure UCb disposed in the different layers. Thus, the moisture penetrating path may be blocked. The second electrode 150 may be disposed on the first connection line CL1 and the organic material layer 145.

Moreover, as shown in FIG. 12, the second undercut structure UCb may be formed under the second source/drain line N_SD2. The second undercut structure UCb may have an undercut shape with respect to the interlayer insulating layer 115. Due to the undercut shape, an end EG12a of the second source/drain line N_SD2 protrudes horizontally beyond an end EG12b of the interlayer insulating layer 115. Thus, the first connection line CL1 disposed on the upper surface of the second source/drain line N_SD2 may be broken or discontinuous. Hence, the first connection line CL1 (or a portion thereof) disposed on the upper surface of the second source/drain line N_SD2 may be isolated (or disconnected) from the first connection line CL1 (or the remaining portion or another portion thereof) disposed on the buffer layer 110. Accordingly, a moisture penetrating path from the first connection line CL1 to the second transmissive area TA2 may be blocked. The second electrode 150 may be disposed on the first connection line CL1 and the organic material layer 145.

Referring to FIG. 13 and FIG. 14 together with FIG. 6A and FIG. 6B, the second connection line CL2 may be disposed between and connected to the first transmissive area TA1 and the third transmissive area TA3 spaced apart from each other in the second direction. The gate electrode line N_GE may extend so as to intersect the second connection line CL2. The buffer layer 110, the gate insulating layer GI, the gate electrode line N_GE, the interlayer insulating layer 115, the protective film 120, the overcoat layer 125, the organic material layer 145, and the second electrode 150 may be disposed on the substrate 100.

A third undercut structure UCc may be formed under the gate electrode line N_GE. The third undercut structure UCc may have an undercut shape with respect to the gate insulating layer GI. Due to the undercut shape, an end EG13a of the gate electrode line N_GE protrudes horizontally beyond an end EG13b of the gate insulating layer GI. Accordingly, a portion of the second connection line CL2 disposed on the upper surface of the gate electrode line N_GE may be broken or discontinuous and thus may be isolated (or disconnected) from a portion of the second connection line CL2 disposed on the buffer layer 110. Therefore, a moisture penetrating path from the second connection line CL2 to the third transmissive area TA3 may be blocked. The second electrode 150 may be disposed on the second connection line CL2 and the organic material layer 145.

Both opposing portions of the overcoat layer 125 may be respectively disposed at both opposing sides of the circuit area CA with the second connection line CL2 interposed therebetween. The first undercut structure UCa may be formed under the overcoat layer 125. The first undercut structure UCa may have an undercut shape with respect to the protective film 120 and the interlayer insulating layer 115. Accordingly, an end EG14a of each of both opposing portions of the overcoat layer 125 disposed at a corresponding opposing side of the circuit area CA with the second connection line CL2 interposed therebetween may protrude outwardly beyond the end EG14b of each of the protective film 120 and the interlayer insulating layer 115. Due to this shape, the organic material layer 145 disposed on the upper surface of the overcoat layer 125 may be broken or discontinuous and thus may be isolated from the second connection line CL2. The second electrode 150 may be disposed on the second connection line CL2 and the organic material layer 145.

Examples of a first blocking channel BCH1 and a second blocking channel BCH2 are illustrated with reference to FIG. 7 to FIG. 14.

In FIG. 7, a side surfaces of the overcoat layer 125 may be disposed at the first blocking channel BCH1 or may form an edge(s) of the first blocking channel BCH1. The first undercut structures UCa may be disposed at the first blocking channel BCH1 or may form an edge(s) of the first blocking channel BCH1. The first connection line CL1 and the second electrode 150 (e.g., the second electrode 150 on the side surfaces of the overcoat layer 125 and the second electrode 150 at or in the first undercut structures UCa) may be disposed at (or in or on) the first blocking channel BCH1. In FIG. 8, the first connection line CL1 (or a portion of the first connection line CL1) and the second electrode 150 may be disposed at (or in or on) the first blocking channel BCH1.

In FIG. 9, side surfaces of the overcoat layer 125 may be disposed at the first blocking channel BCH1 or may form an edge(s) of the first blocking channel BCH1. The first undercut structure UCa may be disposed at the first blocking channel BCH1 or may form an edge(s) of the first blocking channel BCH1. The first connection line CL1 and the second electrode 150 (e.g., the second electrode 150 on the side surfaces of the overcoat layer 125 and the second electrode 150 at or in the first undercut structure UCa) may be disposed at (or in or on) the first blocking channel BCH1. In FIG. 10, the source/drain line N_SD1, the first connection line CL1 (or a middle portion and two opposing portions of the first connection line CL1), and the second electrode 150 may be disposed at (or in or on) the first blocking channel BCH1. The second undercut structure UCb may be disposed at the first blocking channel BCH1 or may form an edge(s) of the first blocking channel BCH1.

The arrangement of the first blocking channel BCH1 in FIGS. 11 and 12 is similar to the arrangement of the first blocking channel BCH1 of FIGS. 9 and 10, except that, among others, the source/drain line N_SD1 is replaced by the source/drain line N_SD2.

In FIG. 13, the gate electrode line N_GE, the second connection line CL2 (or a middle portion and two opposing portions of the second connection line CL2), and the second electrode 150 may be disposed at (or in or on) the second blocking channel BCH2. The third undercut structure UCc may be disposed at the second blocking channel BCH2 or may form an edge(s) of the second blocking channel BCH2. In FIG. 14, side surfaces of the overcoat layer 125 may be disposed at the second blocking channel BCH2 or may form an edge(s) of the second blocking channel BCH2. The first undercut structure UCa may be disposed at the second blocking channel BCH2 or may form an edge(s) of the second blocking channel BCH2. The second connection line CL2 and the second electrode 150 (e.g., the second electrode 150 on the side surfaces of the overcoat layer 125 and the second electrode 150 at or in the first undercut structure UCa) may be disposed at (or in or on) the second blocking channel BCH2.

In one example, the dam pattern 200 is disposed at a corner of the non-pad area NPAD of the non-display area PAD and NPAD to additionally block the moisture penetrating path. Further details are provided with reference to the drawings described below.

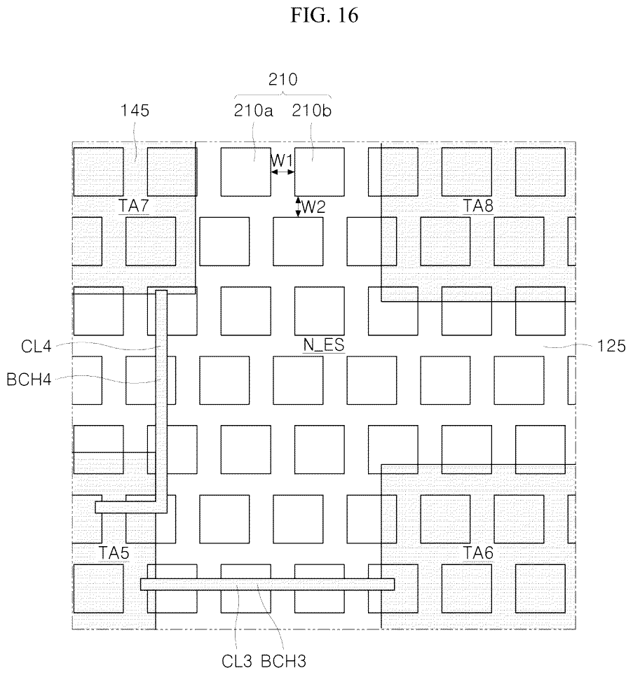

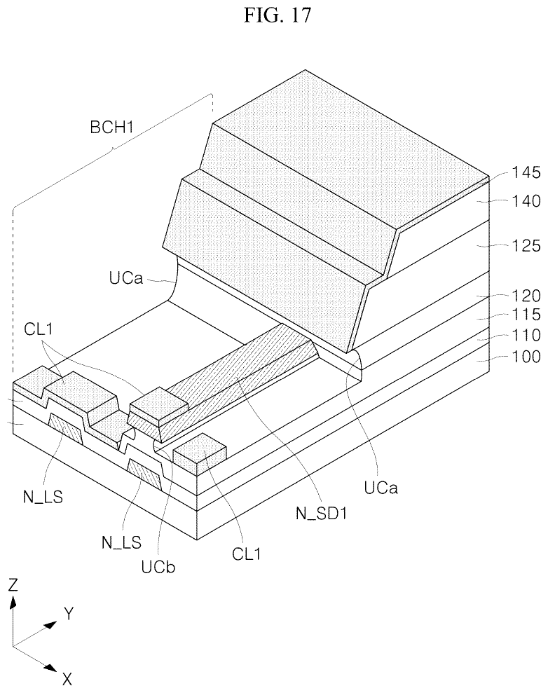

FIG. 15 is an example of an enlarged plan view showing a corner portion of a non-pad area according to another embodiment of the present disclosure. For example, FIG. 15 is an example of an enlarged plan view of an area 15 depicted in FIG. 1. FIG. 16 is an example of an enlarged plan view of an area 16 depicted in FIG. 15.

Referring to FIG. 15 and FIG. 16, in the corner of the non-pad area NPAD, a dam area DAM with the dam pattern 200 may be disposed to prevent the moisture from penetrating from a side surface of the display panel PNL to the display area AA.

A first point De1 where the dam area DAM starts may be disposed adjacent to the outermost position of a gate driver GIP. However, embodiments of the present disclosure are not limited thereto. In another example, the dam area DAM may vertically overlap a partial area of the gate driver GIP, and thus may be disposed on top of the partial area thereof. The gate driver GIP may be implemented using a gate-in-panel (GIP) technique. A barrier pattern BR may be further disposed adjacent to a second point De2 where the dam area DAM ends. However, the present disclosure is not limited thereto.

The non-pad area NPAD may be located on or at the other side edge opposite to the pad area PAD disposed on or at one side edge of the display panel PNL. The dam area DAM may be disposed adjacent to the cutting line CL.

In the display panel PNL which can be cut, an area in which a plurality of sub-pixels are formed extends from the display area AA to the non-pad area NPAD. Thus, The non-pad area NPAD may include an area NPAD_PX in which the sub-pixels are formed and an area NPAD_NPX where the sub-pixels are not disposed. The area NPAD_NPX where the sub-pixels are not disposed may extend from an area where the gate driver GIP is disposed.

As shown in FIG. 16, in the area NPAD_NPX in which the sub-pixels are not disposed, the transmissive areas TA5, TA6, TA7, and TA8 may be disposed adjacent to each other. The transmissive areas TA5, TA6, TA7 and TA8 may include the organic material layer 145. The transmissive areas TA5, TA6, TA7, and TA8 may include a fifth transmissive area TA5, a sixth transmissive area TA6, a seventh transmissive area TA7, and an eighth transmissive area TA8. In this regard, the fifth transmissive area TA5 and the sixth transmissive area TA6 may be spaced apart from each other in the first direction, while a third connection line CL3 may be disposed between and connected to the fifth transmissive area TA5 and the sixth transmissive area TA6. The seventh transmissive area TA7 and the eighth transmissive area TA8 may be spaced apart from each other in the first direction. Moreover, the fifth transmissive area TA5 and the seventh transmissive area TA7 may be spaced apart from each other in the second direction, while the fourth connection line CL4 may be disposed between and connected to the fifth transmissive area TA5 and the seventh transmissive area TA7. Further, the sixth transmissive area TA6 and the eighth transmissive area TA8 may be spaced apart from each other in the second direction.

In this regard, the first direction may be an X-axis direction and the second direction may be a Y-axis direction. However, the present disclosure is not limited thereto. For example, the first direction may be a longitudinal direction, and the second direction may be a transverse direction.

In the area NPAD_NPX where the sub-pixels are not disposed, an empty space area N_ES is disposed between the plurality of transmissive areas TA5, TA6, TA7, and TA8 spaced apart from each other.

In the empty area N_ES, a plurality of signal wiring lines are not disposed and the overcoat layer 125 with the undercut structure disposed thereunder may be disposed, unlike the area NPAD_PX of the non-pad area NPAD in which the sub-pixels are formed.

However, the configuration of the undercut structure disposed under the overcoat layer 125 may have a limitation in blocking the moisture penetrating path that may be composed of the third connection line CL3 and the fourth connection line CL4.

Accordingly, in another embodiment of the present disclosure, a plurality of dummy patterns 210 may be disposed in the area NPAD_NPX in which the sub-pixels are not disposed. The plurality of dummy patterns 210 may be formed, for example, in the same process as a process of forming a source electrode or a drain electrode or a gate electrode in the display area AA. Accordingly, the plurality of dummy patterns 210 may be made of the same material as that of the source electrode or the drain electrode or the same material as that of the gate electrode.

Adjacent dummy patterns 210a and 210b of the plurality of dummy patterns 210 may be spaced apart from each other by predetermined spacings W1 and W2. Each of the plurality of dummy patterns 210 may include a square shape. The plurality of dummy patterns 210 may overlap the transmissive areas TA5, TA6, TA7, and TA8, the third connection line CL3, and the fourth connection line CL4. The plurality of dummy patterns 210 may overlap positions (or locations or areas) where the organic material layer 145, the third connection line CL3 and the fourth connection line CL4 constituting the moisture penetrating path are disposed. In this way, the plurality of dummy patterns 210 disposed in the area NPAD_NPX in which the sub-pixels are not disposed serves to block the moisture penetrating path, thereby delaying the moisture penetration into the display area AA.

Still referring to FIG. 16, a third blocking channel BCH3 may be disposed between transmissive areas arranged in the first direction (e.g., an X-axis direction) among the plurality of transmissive areas TA of the corner area. For example, the third blocking channel BCH3 may be disposed between the fifth transmissive area TA5 and the sixth transmissive area TA6. In addition, a fourth blocking channel BCH4 may be disposed between transmissive areas arranged in the second direction (e.g., a Y-axis direction) among the plurality of transmissive areas TA of the corner area. For example, the fourth blocking channel BCH4 may be disposed between the fifth transmissive area TA5 and the seventh transmissive area TA7. The third connection line CL3 may be disposed at the third blocking channel BCH3. The fourth connection line CL4 may be disposed at the fourth blocking channel BCH4. Furthermore, the plurality of dummy patterns 210 may overlap the third blocking channel BCH3 and the fourth blocking channel BCH4.

In one or more aspects of the present disclosure, a display device may include: a display panel including a display area and a non-pad area located outside the display area; a plurality of transmissive areas disposed in the non-pad area and spaced apart from each other in a first direction and a second direction different from the first direction; a circuit area disposed between adjacent ones of the plurality of transmissive areas; a plurality of connection lines, each connection line being disposed between adjacent ones of the plurality of transmissive areas; and a plurality of wiring lines disposed in the circuit area, wherein each of the plurality of wiring lines extends so as to intersect a corresponding one of the plurality of connection lines, wherein the plurality of wiring lines are disposed in different layers, and wherein a first undercut structure is formed under each of the plurality of wiring lines.

In one or more example implementations, a side end of each of the plurality of wiring lines protrudes outwardly beyond a side end of a corresponding one of the first undercut structures such that each of the plurality of connection lines is broken into a first portion, and opposing second portions, wherein the opposing second portions are isolated from each other, and wherein the first portion is disposed on an upper surface of a corresponding one of the plurality of wiring lines, while the opposing second portions are disposed at opposing sides of the corresponding one of the plurality of wiring lines.

In one or more example implementations, the circuit area further includes an overcoat layer, wherein a second undercut structure is formed under the overcoat layer, wherein the plurality of transmissive areas includes an organic material layer, wherein the organic material layer terminates so as to be discontinuous at a side end of the overcoat layer protruding outwardly beyond a side end of the second undercut structure under the overcoat layer. In one or more example implementations, the second undercut structure is disposed above each of the plurality of connection lines.

In one or more example implementations, the plurality of transmissive area includes an organic material layer, wherein a side end of the overcoat layer protrudes outwardly beyond a corresponding side end of the second undercut structure such that the organic material layer is broken at the side end of the overcoat layer.

In one or more example implementations, the plurality of connection lines includes: a first connection line disposed between transmissive areas arranged in the first direction among the plurality of transmissive areas; and a second connection line disposed between transmissive areas arranged in the second direction among the plurality of transmissive areas.

In one or more example implementations, the plurality of wiring lines includes: a first wiring line extending so as to intersect the first connection line; and a second wiring line extending so as to intersect the second connection line, wherein a layer of the second wiring line is lower than a layer of the first wiring line.

In one or more example implementations, the first wiring line and the second wiring line are disposed in different layers, the first wiring line is disposed in a first layer, and the second wiring line is disposed in a second layer that is lower than the first layer.

In one or more example implementations, the first wiring line includes one of a light blocking layer line and a plurality of source/drain lines extending from the display area to the non-pad area, and a plurality of source/drain lines, wherein the second wiring line includes a gate electrode line extending from the display area to the non-pad area.

In one or more example implementations, the first wiring line or the second wiring line is in a floating state in which the first wiring line or the second wiring line is not electrically connected.

In one or more example implementations, the display device further comprises: a pad area disposed on one side edge of the display panel opposite to the non-pad area; and a cutting line located on the other side edge of the display panel opposite to the pad area, wherein the cutting line may be configured to control a size of the display panel.

In one or more example implementations, the display panel further includes a corner area located at a side edge of the non-pad area, wherein the corner area includes: a plurality of transmissive areas spaced apart from each other in the first direction and the second direction different from the first direction; a third connection line disposed between transmissive areas arranged in the first direction among the plurality of transmissive areas of the corner area; a fourth connection line disposed between transmissive areas arranged in the second direction among the plurality of transmissive areas of the corner area; an overcoat layer disposed in a space between the plurality of transmissive areas of the corner area, wherein a second undercut structure is formed under the overcoat layer; and a plurality of dummy patterns overlapping the plurality of transmissive areas of the corner area, the third connection line, and the fourth connection line.

In one or more example implementations, adjacent ones of the plurality of dummy patterns are spaced apart from each other.

In one or more example implementations, the display device may further include a plurality of transmissive areas and a circuit area disposed in the display area, and an arrangement of the plurality of transmissive areas and the circuit area of the non-pad area is identical to an arrangement of the plurality of transmissive areas and the circuit area of the display area.

In one or more example implementations, the second undercut structure is disposed above (or disposed at least partially above) each of the plurality of connection lines.

In one or more aspects of the present disclosure, a display device may include: a display panel including a display area and a non-pad area located outside the display area; a plurality of transmissive areas disposed in the non-pad area and spaced apart from each other in a first direction and a second direction different from the first direction; a circuit area disposed between adjacent ones of the plurality of transmissive areas; a plurality of blocking channels, wherein each blocking channel is disposed between adjacent ones of the plurality of transmissive areas; and a plurality of wiring lines disposed in the circuit area, wherein each of the plurality of wiring lines extends so as to intersect a corresponding one of the plurality of blocking channels, wherein the plurality of wiring lines are disposed in different layers, and wherein a first undercut structure is formed under each of the plurality of wiring lines.

In one or more example implementations, the display device may further include a plurality of connection lines, wherein each of the plurality of connection lines is disposed at a corresponding one of the plurality of blocking channels, and wherein a side end of each of the plurality of wiring lines protrudes outwardly beyond a side end of a corresponding one of the first undercut structures such that each of the plurality of connection lines is broken into a first portion and opposing second portions.

In one or more example implementations, the opposing second portions may be isolated from each other, wherein the first portion is disposed on an upper surface of a corresponding one of the plurality of wiring lines, while the opposing second portions are disposed at opposing sides of the corresponding one of the plurality of wiring lines.

In one or more example implementations, the circuit area may further include an overcoat layer, wherein a second undercut structure is formed under the overcoat layer.

In one or more example implementations, the plurality of transmissive areas may include an organic material layer, wherein the organic material layer terminates so as to be discontinuous at a side end of the overcoat layer protruding outwardly beyond a side end of the second undercut structure under the overcoat layer.

In one or more example implementations, the display device may further include a plurality of connection lines, wherein each of the plurality of connection lines is disposed at a corresponding one of the plurality of blocking channels, wherein each of the plurality of connection lines includes an organic material layer, and wherein the organic material layer of each of the plurality of connection lines is same as the organic material layer of the plurality of transmissive areas.

In one or more example implementations, the plurality of blocking channels may include: a first blocking channel disposed between transmissive areas arranged in the first direction among the plurality of transmissive areas; and a second blocking channel disposed between transmissive areas arranged in the second direction among the plurality of transmissive areas.

In one or more example implementations, the plurality of wiring lines may include: a first wiring line extending so as to intersect the first blocking channel; and a second wiring line extending so as to intersect the second blocking channel.

In one or more example implementations, the first wiring line and the second wiring line may be disposed in different layers, wherein the first wiring line is disposed in a first layer, and wherein the second wiring line is disposed in a second layer that is lower than the first layer.

In one or more example implementations, the display panel may further include a corner area located at a side edge of the non-pad area. The corner area may include: a plurality of transmissive areas spaced apart from each other in the first direction and the second direction different from the first direction; a third blocking channel disposed between transmissive areas arranged in the first direction among the plurality of transmissive areas of the corner area; and a fourth blocking channel disposed between transmissive areas arranged in the second direction among the plurality of transmissive areas of the corner area.

In one or more example implementations, the corner area may further include: an overcoat layer disposed in a space between the plurality of transmissive areas of the corner area, wherein a second undercut structure is formed under the overcoat layer; and a plurality of dummy patterns overlapping the plurality of transmissive areas of the corner area, the third blocking channel, and the fourth blocking channel.

In one or more example implementations, the display device may further include a plurality of connection lines, wherein each of the plurality of connection lines is disposed at a corresponding one of the plurality of blocking channels, wherein the second undercut structure is disposed at at least one of the plurality of blocking channels, and wherein the second undercut structure is disposed at least partially above at least one of the plurality of connection lines

According to one or more example embodiments of the present disclosure, breaking (or splitting or dividing) the organic material layer which may act as a moisture penetrating path in a display device that can be cut to implement a display device of various sizes may allow the performance and lifespan of the organic light-emitting element to be maintained for a long period.

According to one or more example embodiments of the present disclosure, maintaining the performance and lifespan of the organic light-emitting element for a long period may secure the quality of an image in the display device at a low power level, thereby reducing power consumption.

Moreover, according to one or more example embodiments of the present disclosure, introducing the same array structure, as that of the display area into an area other than the display area in a display device that can be cut may improve the manufacturing process.

Moreover, according to one or more example embodiments of the present disclosure, inserting a dummy pattern into a corner of the non-pad area of the display device that can be cut may further delay (or reduce) the penetration of moisture and oxygen, thereby increasing the lifespan of the display device and further improving reliability.

Moreover, according to one or more example embodiments of the present disclosure, breaking (or splitting) the organic material layer with a multilayer structure in a direction overlapping the direction of the moisture penetrating path in the non-pad area may prevent (or significantly reduce) the penetration of moisture and oxygen into the display area. Accordingly, the lifespan of the organic light-emitting element disposed in the display area may be lengthened, and the display device may operate using low power.

Although the embodiments of the present disclosure have been described in detail with reference to the accompanying drawings, the present disclosure is not necessarily limited to these embodiments, and may be modified in a various manner without departing from the scope of the present disclosure. Accordingly, the embodiments as disclosed in the present disclosure are examples and do not limit the scope of the present disclosure, and the scope of the present disclosure is not limited by these embodiments. Therefore, it should be understood that the embodiments described above are not restrictive but illustrative in all respects. The scope of protection of the present disclosure should be interpreted according to the scope of the claims and their equivalents.

What is claimed is:

1. A display device, comprising:
a display panel including a display area and a non-pad area located outside the display area;
a plurality of transmissive areas disposed in the non-pad area and spaced apart from each other in a first direction and a second direction different from the first direction;
a circuit area disposed between adjacent ones of the plurality of transmissive areas;
a plurality of connection lines, wherein each connection line is disposed between adjacent ones of the plurality of transmissive areas; and
a plurality of wiring lines disposed in the circuit area, wherein each of the plurality of wiring lines extends so as to intersect a corresponding one of the plurality of connection lines,
wherein the plurality of wiring lines are disposed in different layers, and
wherein a first undercut structure is formed under each of the plurality of wiring lines.

2. The display device of claim 1, wherein a side end of each of the plurality of wiring lines protrudes outwardly beyond a side end of a corresponding one of the first undercut structures such that each of the plurality of connection lines is divided into a first portion, and opposing second portions,
wherein the opposing second portions are isolated from each other, and
wherein the first portion is disposed on an upper surface of a corresponding one of the plurality of wiring lines, while the opposing second portions are disposed at opposing sides of the corresponding one of the plurality of wiring lines.

3. The display device of claim 1, wherein the circuit area further includes an overcoat layer, and wherein a second undercut structure is formed under the overcoat layer.

4. The display device of claim 3, wherein the plurality of transmissive areas includes an organic material layer,
wherein the organic material layer terminates so as to be discontinuous at a side end of the overcoat layer protruding outwardly beyond a side end of the second undercut structure such that the organic material layer is broken at the side end of the overcoat layer.

5. The display device of claim 1, wherein the plurality of connection lines includes:
a first connection line disposed between transmissive areas arranged in the first direction among the plurality of transmissive areas; and
a second connection line disposed between transmissive areas arranged in the second direction among the plurality of transmissive areas.

6. The display device of claim 5, wherein the plurality of wiring lines includes:
a first wiring line extending so as to intersect the first connection line; and
a second wiring line extending so as to intersect the second connection line.

7. The display device of claim 6, wherein the first wiring line and the second wiring line are disposed in different layers,
wherein the first wiring line is disposed in a first layer, and
wherein the second wiring line is disposed in a second layer that is lower than the first layer.

8. The display device of claim 6,
wherein the first wiring line includes one of a light blocking layer line and a plurality of source/drain lines extending from the display area to the non-pad area, and
wherein the second wiring line includes a gate electrode line extending from the display area to the non-pad area.

9. The display device of claim 6, wherein the first wiring line or the second wiring line is in a floating state in which the first wiring line or the second wiring line is not electrically connected.

10. The display device of claim 1, wherein the display device further comprises:
a pad area disposed on one side edge of the display panel opposite to the non-pad area; and
a cutting line located on the other side edge of the display panel opposite to the pad area,
wherein the cutting line is configured to control a size of the display panel.

11. The display device of claim 1, wherein the display panel further includes a corner area located at a side edge of the non-pad area,
wherein the corner area includes:
a plurality of transmissive areas spaced apart from each other in the first direction and the second direction different from the first direction;
a third connection line disposed between transmissive areas arranged in the first direction among the plurality of transmissive areas of the corner area;
a fourth connection line disposed between transmissive areas arranged in the second direction among the plurality of transmissive areas of the corner area;
an overcoat layer disposed in a space between the plurality of transmissive areas of the corner area, wherein a second undercut structure is formed under the overcoat layer; and
a plurality of dummy patterns overlapping the plurality of transmissive areas of the corner area, the third connection line, and the fourth connection line.

12. The display device of claim 11, wherein adjacent ones of the plurality of dummy patterns are spaced apart from each other.

13. The display device of claim 1, further comprising:
a plurality of transmissive areas and a circuit area disposed in the display area,
wherein an arrangement of the plurality of transmissive areas and the circuit area of the non-pad area is identical to an arrangement of the plurality of transmissive areas and the circuit area of the display area.

14. The display device of claim 3, wherein the second undercut structure is disposed at least partially above each of the plurality of connection lines.

15. A display device comprising:
a display panel including a display area and a non-pad area located outside the display area;
a plurality of transmissive areas disposed in the non-pad area and spaced apart from each other in a first direction and a second direction different from the first direction;
a circuit area disposed between adjacent ones of the plurality of transmissive areas;
a plurality of blocking channels, wherein each blocking channel is disposed between adjacent ones of the plurality of transmissive areas; and
a plurality of wiring lines disposed in the circuit area, wherein each of the plurality of wiring lines extends so as to intersect a corresponding one of the plurality of blocking channels,
wherein the plurality of wiring lines are disposed in different layers, and
wherein a first undercut structure is formed under each of the plurality of wiring lines.

16. The display device of claim 15, further comprising a plurality of connection lines,
wherein each of the plurality of connection lines is disposed at a corresponding one of the plurality of blocking channels, and
wherein a side end of each of the plurality of wiring lines protrudes outwardly beyond a side end of a corresponding one of the first undercut structures such that each of the plurality of connection lines is broken into a first portion and opposing second portions.

17. The display device of claim 16, wherein the opposing second portions are isolated from each other, and
wherein the first portion is disposed on an upper surface of a corresponding one of the plurality of wiring lines, while the opposing second portions are disposed at opposing sides of the corresponding one of the plurality of wiring lines.

18. The display device of claim 15, wherein the circuit area further includes an overcoat layer, wherein a second undercut structure is formed under the overcoat layer.

19. The display device of claim 18, wherein the plurality of transmissive areas includes an organic material layer,
wherein the organic material layer terminates so as to be discontinuous at a side end of the overcoat layer protruding outwardly beyond a side end of the second undercut structure under the overcoat layer.

20. The display device of claim 19, further comprising a plurality of connection lines,
wherein each of the plurality of connection lines is disposed at a corresponding one of the plurality of blocking channels,
wherein each of the plurality of connection lines includes an organic material layer, and
wherein the organic material layer of each of the plurality of connection lines is same as the organic material layer of the plurality of transmissive areas.

21. The display device of claim 15,
wherein the plurality of blocking channels includes:
a first blocking channel disposed between transmissive areas arranged in the first direction among the plurality of transmissive areas; and
a second blocking channel disposed between transmissive areas arranged in the second direction among the plurality of transmissive areas.

22. The display device of claim 21, wherein the plurality of wiring lines includes:
a first wiring line extending so as to intersect the first blocking channel; and
a second wiring line extending so as to intersect the second blocking channel.

23. The display device of claim 22, wherein the first wiring line and the second wiring line are disposed in different layers,
wherein the first wiring line is disposed in a first layer, and
wherein the second wiring line is disposed in a second layer that is lower than the first layer.

24. The display device of claim 15, wherein the display panel further includes a corner area located at a side edge of the non-pad area,
wherein the corner area includes:
a plurality of transmissive areas spaced apart from each other in the first direction and the second direction different from the first direction;
a third blocking channel disposed between transmissive areas arranged in the first direction among the plurality of transmissive areas of the corner area; and
a fourth blocking channel disposed between transmissive areas arranged in the second direction among the plurality of transmissive areas of the corner area.

25. The display device of claim 24, wherein the corner area further includes:
an overcoat layer disposed in a space between the plurality of transmissive areas of the corner area, wherein a second undercut structure is formed under the overcoat layer; and
a plurality of dummy patterns overlapping the plurality of transmissive areas of the corner area, the third blocking channel, and the fourth blocking channel.

26. The display device of claim 18, further comprising a plurality of connection lines,
wherein each of the plurality of connection lines is disposed at a corresponding one of the plurality of blocking channels,
wherein the second undercut structure is disposed at at least one of the plurality of blocking channels, and
wherein the second undercut structure is disposed at least partially above at least one of the plurality of connection lines.
